(19) United States
(12) Patent Application Publication
(10) Pub. No.: US 2018/0298792 A1
(43) Pub. Date: Oct. 18, 2018

(54) INTERNAL COMBUSTION ENGINE COMPONENT AND PRODUCING METHOD THEREFOR

(71) Applicants: KOBE CERAMICS CORPORATION, Suita-shi, Osaka (JP); NITTAN VALVE CO., LTD., Hadano-shi, Kanagawa (JP)

(72) Inventors: Hideo Torii, Suita-shi (JP); Takayoshi Suzuki, Suita-shi (JP); Masaaki Inoue, Hadano-shi (JP)

(21) Appl. No.: 15/554,046

(22) PCT Filed: Jun. 30, 2015
(86) PCT No.: PCT/JP2015/068922

§ 371 Date: May 23, 2018

(30) Foreign Application Priority Data
Mar. 14, 2015 (JP) 2015-051506

(51) Int. Cl. F01L 3/02; C23C 14/34; C23C 28/00; C23C 18/12; F02F 3/00

(52) U.S. Cl. CPC F01L 3/02; C23C 14/34; F01L 2101/00; C23C 18/1216; F02F 3/0084; C23C 28/345

(57) ABSTRACT

Provided is an internal combustion engine component in which a satisfactory heat insulating property is combined with durability superior to that in the related art. The internal combustion engine component constitutes the inner wall surface of the combustion chamber of an internal combustion engine, wherein (1) in the component, a porous layer is formed at least on a surface exposed to the combustion chamber, and (2) the porous layer is a layer formed by three-dimensionally interconnected grains of a ferrite which is spinel type iron oxide.

### TECHNICAL FIELD

The present invention relates to a novel internal combustion engine component and a method for producing the same.

### BACKGROUND ART

Various internal combustion engines that continuously convert thermal energy into work have been developed. Among them, automobile engines have been improved in many aspects to save energy and protect environment. In recent years, in particular, in order to save energy, efforts have been made to further improve the efficiency of energy conversion between heat and work by forming a porous layer on each surface directly exposed to a combustion flame in internal combustion engine components constituting the inner wall of the combustion chamber of the engine, for example, the combustion surface of the valve head of an intake valve, the combustion surface of the valve head of an exhaust valve, the top surface of a piston, the combustion surface of a cylinder head, the inner wall surface of the cylinder liner, and the like.

For example, in automobile engines and the like, it is necessary to increase the conversion efficiency of the expansion pressure generated by explosive combustion of a fuel mixed gas in the engine cylinder into mechanical energy (kinetic energy). Therefore, by providing the heat insulating film on the surface exposed to the combustion chamber in engine valves or the like, the generated thermal energy is maintained during explosive combustion. As a result, the pressing force of the piston can be taken out more efficiently. Meanwhile, at the time of intake, an adiabatic membrane is instantaneously cooled by the cold fuel mixed gas flowing in from an intake valve. As a result, the expansion of air flowing into the combustion chamber is suppressed and air having a high oxygen concentration is introduced into the combustion chamber, thereby making it possible to increase the efficiency of explosive combustion.

An internal combustion engine is known in which, for example, the wall surface of a combustion chamber such as the top surface of a piston, the lower surface of a head, a liner or the like of the internal combustion engine is coated with a porous heat insulating material having a porosity of 80% or more as such a heat insulating film (Patent Document 1).

Further, for example, regarding an engine valve which is an important internal combustion engine component, a heat insulated component has been disclosed in which a porous ceramic coating formed of a thermally sprayed film of zirconia (ZrO₂) having a thermal conductivity lower than that of the metallic material of the valve base material is formed on the combustion surface of the valve head of the valve constituting the wall surface in the combustion chamber (Patent document 2).

Also, an internal combustion engine has been suggested in which in addition to the objective of increasing thermal efficiency, in order to improve the durability of a heat insulating film against thermal cycle fatigue, the heat insulating film includes a first heat insulating material having a thermal conductivity lower than that of a base material and a heat capacity per unit volume also lower than that of the base material, and a second heat insulating material which has a thermal conductivity equal to or lower than that of the base material and serves for protecting the first heat insulating material from the combustion gas in the combustion chamber, the first heat insulating material has a thermal conductivity lower than that of the second heat insulating material and a heat capacity per unit volume also lower than that of the second heat insulating material, the heat insulating film has admixed thereto a reinforcing material for reinforcing the heat insulating film, the second heat insulating material is zirconia, silicon, titanium, zirconium, ceramic, ceramic fiber, or a combination of a plurality thereof, and the first insulating material is hollow ceramic beads, hollow glass beads, a heat insulating material of a microporous structure, silica air-gel, or a combination of a plurality thereof (Patent Document 3).

Further, among the internal combustion engine components, the following engine valve which is particularly required to have durability and reliability has been suggested. Thus, an engine valve is known which has a valve body including a valve stem and a valve head and which opens and closes a port opened in the combustion chamber of an engine. In this valve, a concave portion recessed from the valve head surface is formed in the valve head surface facing the combustion chamber in the valve head in the part of the surface excluding a central portion, an outer peripheral portion, and an intermediate portion therebetween, and there are further provided a porous material which is loaded into the concave portion so that the concave portion contains air, and a coating film which has a thermal conductivity lower than that of the valve body and covers the valve head surface including the concave portion by joining to at least the central portion, the outer peripheral portion, and the intermediate portion of the valve head surface (Patent document 4).

Techniques using a heat insulating film have also been suggested in other technical field (Patent document 5 and the like), but these techniques are not intended for use under severe conditions such as those of engine valves, and research and development relating to such conditions have not been performed.

### CITATION LIST

### Patent Document

[Patent document 1] Japanese Patent Application Publication No. S60-182340
[Patent document 2] Japanese Patent Application Publication No. H4-311611
[Patent document 3] Japanese Patent No. 5082987
[Patent document 4] Japanese Patent No. 5625690
[Patent document 5] Japanese Patent No. 4966437

### SUMMARY OF INVENTION

### Technical Problem

Although a predetermined heat insulating property can be obtained in internal combustion engine components in which such porous layers (heat insulating films) are arranged, there is still room for improvement. Thus, internal combustion engine components (in particular, the components constituting the inner wall surface of a combustion chamber) need to be provided not only with a heat insulating property (low thermal conductivity), but also with durability such as oxidation resistance, deflection resistance, thermal shock resistance and the like.

Concerning the oxidation resistance, in a combustion chamber where a combustion flame of 800° C. or higher is generated, the components are always exposed to the combustion flame gas atmosphere, so that the material thereof is required not to deteriorate even in such an atmosphere.

Concerning the deflection resistance, working components, for example, represented by engine valves, are continuously subjected to contact, friction and the like with other members (in the case of engine valves, contact and friction with the valve seat), and in such a case, the components themselves will deflect instantaneously. It is required that even in such a case, the heat insulating film does not peel, fall off or the like. In other words, the ideal heat insulating film have properties such that allow the film to follow the deformation of the member.

Concerning the thermal shock resistance, since the combustion explosion and intake cycles are repeated in the combustion chamber of the engine, it is necessary to withstand continuously a sudden temperature difference (contraction/expansion) during heating/cooling.

Accordingly, it is highly desirable to develop the internal combustion engine components, particularly the components constituting the combustion chamber, in which heat insulating property (low thermal conductivity) is combined with durability such as oxidation resistance, deflection resistance, and thermal shock resistance, but this requires the improvement of the conventional components in terms of physical properties thereof.

Therefore, it is a primary object of the present invention to provide an internal combustion engine component in which a satisfactory heat insulating property is combined with durability superior to that in the related art. In particular, it is another object of the present invention to provide an engine valve in which a heat insulating property (low thermal conductivity) is combined with durability such as oxidation resistance, deflection resistance, thermal shock resistance and the like.

### Solution to Problem

The inventors of the present invention have conducted extensive research in view of the problems of the related art and, as a result, have found that a member having a specific structure can achieve the above object. This finding led to the completion of the present invention.

That is, the present invention relates to the following internal combustion engine component and a method for producing the same.

1. An internal combustion engine component constituting an inner wall surface of a combustion chamber of an internal combustion engine, wherein

(1) in the component, a porous layer is formed at least on a surface exposed to the combustion chamber, and

(2) the porous layer is a layer formed by three-dimensionally interconnected grains of a ferrite which is an iron oxide.

2. The internal combustion engine component according to the above 1, wherein

the porous layer is formed of dendritic clusters of the ferrite that continuously extend upward from

1) a surface of a base material of the component or

2) a surface of a metallic film which has been formed in advance on the surface of the base material of the component.

3. The internal combustion engine component according to the above 1, wherein the porous layer is formed by a hydrothermal synthesis reaction of 1) a surface of a base material of the component or 2) a surface of a metal film which has been formed in advance on the surface of the base material of the component, and an aqueous solution or an aqueous dispersion including an iron component.

4. The internal combustion engine component according to the above 1, wherein the ferrite which is a spinel type oxide is an oxide having a spinel type crystal structure represented by a following general formula: AₓFe₃₋ₓO₄ (where A represents at least one kind of metal element substitutable for a Fe site constituting a crystal of a spinel type iron oxide, and x satisfies 0≤x<1).

5. The internal combustion engine component according to the above 4, wherein A is at least one of Al, Mg, Mn, and Zn.

6. The internal combustion engine component according to the above 1, wherein a base material is made of iron or an alloy including the same.

7. The internal combustion engine component according to the above 1, wherein a surface of a base material is nitrided in advance.

8. The internal combustion engine component according to the above 2 or 3, wherein a metal layer comprises an iron-containing layer.

9. The internal combustion engine component according to the above 8, wherein the metal layer has two or more layers of different materials, and a layer in contact with the porous layer is the iron-containing layer.

10. The internal combustion engine component according to the above 1, wherein the porous layer has a thickness of 40 μm or more.

11. The internal combustion engine component according to the above 1, wherein the component is a valve.

12. The internal combustion engine component according to the above 1, wherein the component is a piston.

13. A method for producing an internal combustion engine component having, on the surface thereof, a porous layer formed by three-dimensionally interconnected grains of a ferrite which is an iron oxide, the method including a step of causing a hydrothermal synthesis reaction of 1) a surface of a base material of the component or 2) a surface of a metallic layer which has been formed in advance on the surface of the base material of the component, and an aqueous solution or an aqueous dispersion including an iron component, to form the porous layer on the surface.

14. The production method according to the above 13, including, as the hydrothermal synthesis reaction, a step of performing heat treatment under an environment at or above a saturated water vapor pressure at 105° C. to 150° C. in a state in which 1) the surface of the base material of the component or 2) the surface of the metallic layer which has been formed in advance on the surface of the base material of the component, is in contact with a treatment liquid obtained by mixing a metal salt, an alkali, and water.

15. The production method according to the above 13, wherein the metallic layer is formed by a plating method or a sputtering method.

16. The production method according to the above 13, wherein the hydrothermal synthesis reaction is carried out in the presence of a reducing agent.

### Advantages of Invention

According to the present invention, since the internal combustion engine component, in particular a valve for an automobile engine, which is particularly required to have durability as such a component, has on the surface thereof a porous layer having a specific structure, it is possible to obtain the following profitable effects.

(1) Since the porous layer has a low thermal conductivity (excellent thermal insulating property) and a low specific heat (heat capacity per unit volume), it is possible to obtain a high combustion efficiency in the combustion chamber of the engine. Thus, since the porous layer has a structure formed by three-dimensional interconnection of crystal grains of a ceramic material called ferrite, high heat insulating property and low specific heat (heat capacity per unit volume) can be exhibited. As a consequence, it is possible to maintain effectively the generated thermal energy at the time of explosive combustion, and also to suppress the expansion of air flowing into the combustion chamber at the time of intake and introduce air having a higher oxygen concentration into the combustion chamber. As a result, a contribution can be made to the improvement in combustion efficiency of the internal combustion engine (engine).

(2) Since the porous layer is formed integrally with the surface of the base material of the component or the surface of the metallic layer, the porous layer can exhibit excellent performance in deflection resistance, thermal shock resistance and the like. Thus, since the porous layer is constituted by clusters of ferrite grains grown from the surface of the base material of the component or the surface (diffusion layer) of the metallic layer, and is in a state of being integrated with these surfaces, the porous layer is unlikely to peel off, fall off or the like, unlike the layers formed by general coating techniques.

At the same time, since a structure is realized in which clusters of ferrite grains extend from the surface as independent dendrites, the entire porous layer can follow the deflection of the member main body, without being fractured. As a result, excellent deflection resistance can be exhibited.

Further, since the porous layer includes a ferrite which is an iron oxide as a constituent component, excellent oxidation resistance inherent to ferrites can be obtained.

(3) The component of the present invention having such characteristics can be advantageously used as an engine valve, a piston, and the like which are components constituting the inner wall of the combustion chamber. As a result, it is possible to provide an internal combustion engine with better combustion efficiency.

### BRIEF DESCRIPTION OF DRAWINGS

FIG. 1 is a schematic sectional view of the combustion chamber of an engine.

FIG. 2 is a schematic view including partly fractured surfaces of an intake valve and an exhaust valve as components of the present invention; FIG. 2(a) shows the intake valve; and FIG. 2(b) shows the exhaust valve.

FIG. 3 is a schematic cross-sectional view of the surface of an internal combustion engine component on which a porous layer has been formed.

FIG. 4 is a view showing a production process of an engine valve in Example 1.

FIG. 5 is an X-ray diffraction pattern diagram of the porous layer in Example 1.

FIG. 6 is a diagram showing a scanning electron microscopic image of a cross section of the porous layer in Example 1; FIG. 6(1) shows the state before a bending test; and FIG. 6(2) shows the state after the bending test.

FIG. 7 is a view showing an observation result of a cross section including the porous layer in Example 1.

FIG. 8 is a schematic diagram of a device for evaluating heat insulating performance of the engine valve in Example 1.

FIG. 9 is a view showing a result of evaluating the heat insulating property of the engine valve in Example 1.

FIG. 10 is a schematic diagram showing a durability test evaluation device for the engine valve in Example 1.

FIG. 11 is a diagram showing a durability test evaluation result of the engine valve in Example 1.

FIG. 12 is a view showing a change in the appearance of the porous layer at each elapsed time in the durability test of the engine valve in Example 1.

FIG. 13 is an X-ray diffraction pattern diagram of a porous layer in Example 5.

FIG. 14 is a view showing the results of observing the surface of the porous layer in Example 5.

FIG. 15 is a schematic sectional view of a piston in Example 13.

FIG. 16 is a diagram (SEM image) showing the results of observing the surface of the porous layer formed in each example with a scanning electron microscope.

### REFERENCE SIGNS LIST

1 Internal combustion engine
2 Combustion chamber
3 Cylinder head
4 Cylinder liner
5, 6, 32, 42 Engine valves
7 Piston
8 Spark plug
11, 12 Combustion surface of valve head
13, 14 Valve face
15, 16 Fillet of valve head
17, 18 Upper head region R
19, 20 Valve stem
21 Porous layer
22 Base material
23 Metallic layer
24 Resin paint coating film
31 Heat insulating property evaluating device
33 Heater controller
34 Air flow rate controller
35 Air compressor
36 Test sample heating mechanism
37 Heater
38 Thermocouple for heater control
39 Thermocouple for temperature measurement
40 Temperature recorder
41 Durability test evaluation device
43 Valve drive unit
44 Combustion burner heating mechanism
45 Valve seat
46 Valve vertical movement mechanism
47 Valve rotation mechanism
48 Water cooling mechanism
49 Flame

### DESCRIPTION OF EMBODIMENTS

1. Internal Combustion Engine Component

The internal combustion engine component (component of the present invention) of the present invention is a component constituting an inner wall surface of a combustion chamber of an internal combustion engine, wherein

(1) in the component, a porous layer is formed at least on a surface exposed to an atmosphere within the combustion chamber, and

(2) the porous layer is a layer formed by three-dimensionally interconnected grains of a ferrite which is an iron oxide.

As described above, in the basic configuration of the component of the present invention, the specific porous layer is formed as the outermost layer on the entire surface of the internal combustion engine component or a part thereof, but other layers may be included if necessary. In particular, the component of the present invention is characterized in that the porous layer is formed on the surface exposed to the combustion chamber. Therefore, when the combustion chamber is assembled using the component of the present invention, the porous layer which is the outermost layer is exposed to an atmosphere within the combustion chamber.

Further, in the present invention, in various applications, it is also possible to form the porous layer in a region other than the inner wall surface of the combustion chamber. As a result, it is possible to protect the base material from heat-induced deterioration and the like more effectively. For example, in the case of application to the exhaust valve of an engine, the heat-induced deterioration of the engine valve can be more effectively reduced or prevented by providing the porous layer not only on the combustion surface of the valve head on the inner wall surface side of the combustion chamber, but also in other regions (for example, on the fillet of the valve head), so as to reduce the portion where the base material is directly exposed to an atmosphere within the exhaust gas.

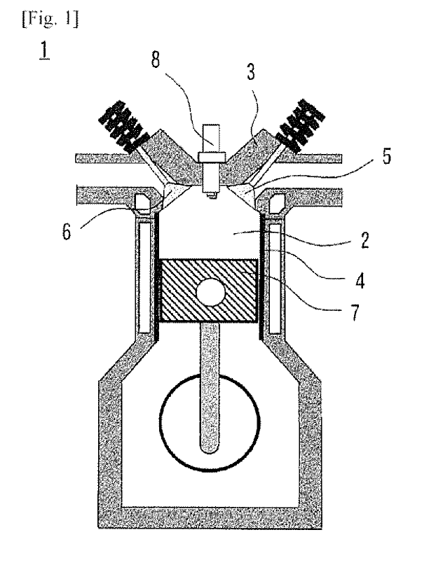

As a representative example of an internal combustion engine, FIG. 1 shows, with respect to an automotive gasoline engine, a cross-sectional schematic view of an internal combustion engine 1 around a combustion chamber. The main components constituting the combustion chamber 2 of the internal combustion engine can be exemplified by a cylinder head 3, a cylinder liner 4, two engine valves 5, 6, a piston 7, an ignition plug 8 and the like. The inner wall surface of the combustion chamber 2 of the internal combustion engine can include the combustion surface of the valve head of the intake valve 5, the combustion surface of the valve head of the exhaust valve 6, the top surface of the piston 7, the lower surface of the cylinder head 3, and the inner wall surface of the cylinder liner 4. Thus, the porous layer can be formed on these surfaces.

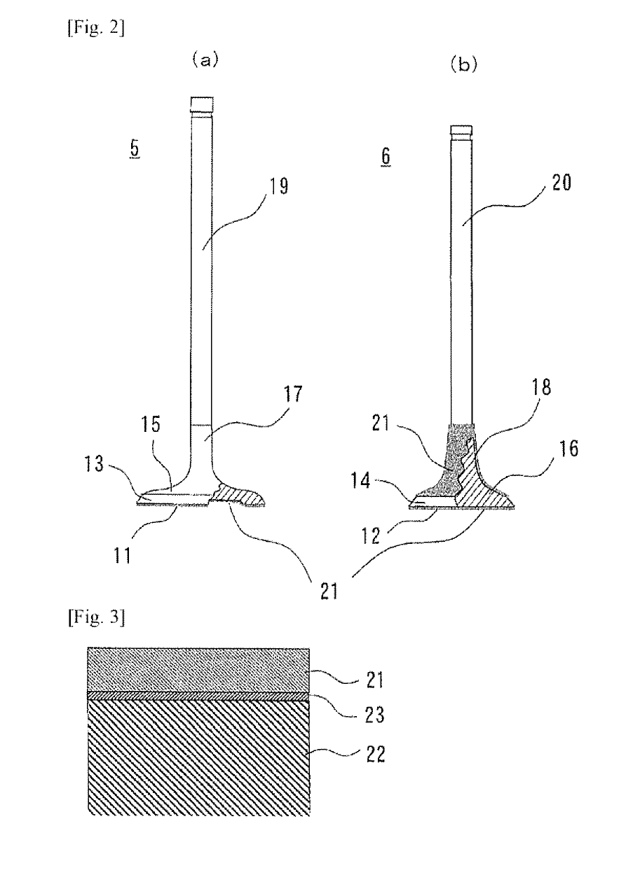

Among these components, the two engine valves 5, 6 are required to have a long service life and high mechanical durability against severe thermal cycles. FIG. 2 is a schematic view including partly fractured surfaces of the two engine valves 5, 6. With respect to the intake valve 5 shown in FIG. 2(a), the porous layer 21 is formed on the combustion surface 11 of the valve head. With respect to the exhaust valve 6 shown in FIG. 2(b), the porous layer 21 is formed on the 1) combustion surface 12 of the valve head, 2) fillet 16 of the valve head excluding the valve face 14, and 3) an upper head region 18 connected to the fillet 16 of the valve head, respectively.

FIG. 3 is a schematic diagram of an enlarged cross section of a portion of the porous layer 21 formed on the surface of the base material 22 of an internal combustion engine component such as an engine valve. As to the porous layer 21, a porous layer formed by three-dimensionally interconnected grains of a ferrite which is an iron oxide is formed as the outermost layer on the surface of the base material 22, with a metallic layer 23 being interposed therebetween. As a result, the porous layer 21 is exposed to the combustion chamber (space).

More specifically, the porous layer 23 has a structure in which ferrite crystal grains having different sizes are piled up and bonded to form a three-dimensional interconnection. In particular, according to the production method of the present invention, ferrite crystal grains of iron oxide are generated by growth on the surface of a metallic layer (the uppermost layer is a metallic iron film) covering the surface of the base material. Furthermore, the ferrite crystal grains of a similar figure but different sizes are piled up and bonded to form a three-dimensionally interconnected structure. For example, as shown in FIG. 7, the porous layer is formed as an assembly of a large number of clusters (denoted by the reference symbol a in FIG. 7) in which ferrite crystals generated from the surface subjected to a hydrothermal synthesis reaction (under hydrothermal treatment) extend upward like independent dendrites.

As a result, excellent heat insulating properties and small specific heat can be obtained, and ferrite grains are directly grown (formed) from a metallic layer integrally formed on the base material. As a result, excellent adhesion can be also realized. Furthermore, since the porous layer has a configuration like an aggregate of individual clusters as described above, the porous layer can flexibly follow the mechanical “bending deformation” of the base material. As a result, high durability can be also demonstrated.

Further, in the present invention, formation of the metallic layer 23 may be omitted depending on the material (composition) of the base material 22, but by providing the metallic layer 23 as shown in FIG. 3, it is possible to improve further the bonding property between the base material 22 and the porous layer 21.

Hereinafter, the base material and the porous layer of the internal combustion engine component of the present invention, and also each layer of the metallic layer will be described.

Base Material

The base material of the component of the present invention may be made of a metal, and the same metal material as that used in known or commercially available internal combustion engines can be used. Examples thereof include metals (single metal) such as iron, aluminum, titanium, chromium, and also alloys such as carbon steel, stainless steel, copper alloys, titanium alloys and the like.

In particular, from the viewpoint of achieving both hardness and workability, it is preferred that an iron-based metal be used as the base material of the component body in the component of the present invention. Thus, it is preferable to use at least one iron-based metal such as metal iron and an iron alloy. The iron alloy is not particularly limited, and for example, carbon steel, stainless steel (SUS), chromium molybdenum steel, a nickel-based heat resistant alloy such as Inconel, or the like can be advantageously used.

Further, in the present invention, it is also possible to use a surface-treated base material. For example, a base material having a nitride film formed by nitriding the surface can also be advantageously used. Durability can be improved by nitriding the surface of the base material in advance. For example, in the case where the component of the present invention is an engine valve, by forming a surface hardening layer (nitride layer) on the face of the engine valve, it is possible to prevent metal touch between the valve seat and the face and to ensure wear resistance of the valve stem and also face portion of the valve. The nitriding process itself can be carried out according to a known method.

Porous Layer

On the surface of the component of the present invention, a porous layer formed by three-dimensionally interconnected grains of a ferrite which is an iron oxide is formed on at least part of the surface that is exposed to an atmosphere within the combustion chamber.

In the present invention, by using ferrite which is one type of iron oxide among metal oxides, it is possible to obtain a higher heat insulating property and, at the same time, high adhesion to the metal base material or metallic layer which is an underlayer can be exerted. It is preferable, as described hereinbelow, that the crystal grains of the ferrite constituting the porous film have a spinel type crystal structure. Morphologically, the porous layer is not particularly limited. For example, a porous layer in which ferrite crystal grains having different sizes are piled up and bonded to form a three-dimensional interconnection can be used.

With such a porous layer of ferrite, high heat insulation properties and low specific heat are performed at the time of using the component of the present invention. As a result, it is possible to improve the combustion efficiency in the internal combustion engine. The form and the like of the porous layer are not particularly limited as long as the porous layer is formed by three-dimensionally interconnected ferrite grains. For example, the porous layer may have a structure in which a plurality of polyhedral crystal grains having one or two or more corner portions, not having a rounded shape, is interconnected.

Further, the bonding state of the ferrite crystal grains is not particularly limited, and may be produced, for example, by crystal twinning growth, or by simple interconnection and fixation of a plurality of crystals. The size of the crystal grains constituting the porous layer can be appropriately controlled by synthesis conditions and the like.

In the present invention, the ferrite is preferably a compound having a spinel type crystal structure represented by the following general formula:

AₓFe₃₋ₓO₄

(where A represents at least one kind of metal element substitutable for a Fe site constituting the crystal of a spinel type iron oxide, and x satisfies 0≤x<1).

The thermal conductivity of iron ferrite (=magnetite (Fe₃O₄)) having a spinel type crystal structure is 6.2 W/m·K at room temperature and 3.5 W·m⁻¹·K⁻¹ at 400° C. In contrast, since the ferrite layer of the component of the present invention is porous, it shows lower thermal conductivity. Further, the volumetric specific heat of iron ferrite having a spinel type crystal structure is 5.6 J·cm⁻³·K⁻¹ at 530° C. On the other hand, since the ferrite layer is porous, it shows lower volumetric specific heat. Therefore, the porosity of the porous layer of the component of the present invention is not particularly limited as long as it can be set so as to obtain thermal conductivity lower than that of the material having the same composition and theoretical density.

Since x satisfies the condition of 0≤x<1, the case where x=0, that is, the case of iron ferrite (that is, spinel type iron oxide Fe₃O₄) is included, and in addition, a composition in which some of Fe sites are substituted with another metal element may be also used.

The aforementioned A is not limited as long as it is at least one kind of metal element substitutable for a Fe site constituting the crystal of a spinel type iron oxide, but it is particularly desirable that A be at least one of Al, Mg, Mn, and Zn. Therefore, in the present invention, a composition in which the component A is at least one of Al, Mg, Mn, and Zn may be used. Such a composition itself may be any known one, for example, at least one of AlFe₂O₄, MgFe₂O₄, MnFe₂O₄, ZnFe₂O₄ and the like.

The thickness of the porous layer can be appropriately set usually within a range of about 40 μm to 500 μm, in particular, depending on the desired heat insulating property and the like, but from the standpoint of more reliably obtaining excellent durability in combination with satisfactory heat insulating properties, the thickness is usually about 50 μm to 350 μm, and particularly preferably 60 μm to 100 μm.

In particular, it is desirable that the porous layer be formed by a hydrothermal synthesis reaction of 1) the surface of the base material of the component or 2) the surface of a metallic layer which has been formed in advance on the surface of the base material of the component, and an aqueous solution or an aqueous dispersion containing an iron component. The porous layer formed in this way is formed integrally with the base material or the metallic layer serving as an underlayer. As a result, the porous layer can be firmly bonded and fixed to the base material. The method and conditions of the hydrothermal synthesis reaction will be explained in section 2. hereinbelow.

The reason why a porous layer can be advantageously formed by a hydrothermal synthesis reaction is unclear, but it is thought to be due to the following mechanism. First, the surface of the base material or the metallic layer serving as an underlayer is slightly dissolved by the treatment liquid, the metal ions generated at that time react with the treatment liquid, and growth nuclei of the aforementioned porous layer are initially generated on the surface of the base material or the metallic layer. Then, crystals grow or increase upward from the growth nuclei as starting points, so that a homogeneous strongly adhering porous layer is formed. Thus, by the hydrothermal synthesis reaction such as described above, a porous layer having a structure formed of assemblies of dendritic clusters of the ferrite that continuously extend upward from the surface of the base material or the metallic layer can be formed more advantageously.

Metallic Layer

The porous layer in the component of the present invention can be formed directly on the surface of the base material of the component, but in order to further enhance the bonding property between the porous layer and the base material, as shown in FIG. 3, a metallic layer (underlayer) 23 may be formed as an underlayer of the porous layer 21, if necessary. In this case, it is desirable that the metallic layer 23 be formed between the surface of the base material 22 and the porous layer 21 in contact with the base material 22 and the porous layer 21.

The composition of the metallic layer is not particularly limited as long as the above purpose can be achieved, and examples thereof include metals such as iron, titanium, nickel, and chromium, and alloys thereof. In particular, a composition including a metal element constituting the porous layer can be used as the underlayer of the porous layer. Therefore, such a metallic layer preferably has a composition including iron (furthermore, a composition including iron as a main component).

Further, the metallic layer may be a single layer or may be formed of two or more layers. For example, a metal film capable of strongly bonding with the base material can be formed as a metallic layer in contact with a base material, and an iron-containing layer capable of strongly bonding with the porous layer can be formed as a metallic layer in contact with the porous layer. Accordingly, it is preferable that a material capable of forming an alloy or an intermetallic compound with the base material (particularly a material which is likely to form an alloy or intermetallic compound with the base material) be used as the metallic layer in contact with the base material, and a metal film containing the same material as the main component (that is, iron) of the porous layer be used as the metallic layer in contact with the porous layer. More specifically, in the case where the base material is a heat-resistant stainless steel or the like, it is most desirable that a nickel film (nickel strike plating film) be used as a metallic layer in contact with the base material, and an iron film (iron plating film) be used as a metallic layer in contact with the porous layer. Therefore, a composite film of a nickel film and an iron film can be advantageously used as the metallic layer.

Where the component of the present invention is an engine valve, it is sometimes necessary to further enhance the bonding property for the purpose of preventing peeling caused by a severe temperature change between a high temperature at the time of combustion and a low temperature at the time of intake. In such a case, a composite film of three or more layers formed by interposing one or two or more different kinds of metallic layers in the middle of the aforementioned composite layer formed of two layers can also be used as the metallic layer.

The thickness of the metallic layer (or the total thickness in the case of two or more layers) can be appropriately set within a range of 2 μm to 15 μm depending on the type of the component and the like. For example, when the component is used as an engine valve or the like, the thickness is usually about 4 μm to 10 μm, and preferably may be 5 μm to 8 μm. By setting such a thickness, it is possible to form effectively the porous layer. In the case of using a two-layer metallic layer formed of a nickel film and an iron film as described above, it is desirable that the nickel film have a thickness of about 0.5 μm to 1 μm and the iron film have a thickness of about 3 μm to 9.5 μm.

As a method for forming the metallic layer, for example, a known method can be appropriately used according to the type of the metal to be used, the composition of the underlying layer, and the like. For example, various well-known thin film forming methods such as a plating method (liquid phase growth method) such as electrolytic plating or electroless plating and the like; a chemical vapor deposition method such as thermal CVD, MOCVD, or RF plasma CVD and the like; and a physical vapor deposition method such as a sputtering method, an ion plating method, an MBE method, a vacuum vapor deposition method and the like can be appropriately used singly or in combination of two or more thereof. In particular, in the present invention, from the viewpoint of obtaining stronger bonding, it is particularly desirable that a (additional) metallic layer be formed on the surface of the base material by the strike plating method.

2. Method for Producing Internal Combustion Engine Component

The internal combustion engine component of the present invention can be advantageously manufactured, for example, by the following method. Thus, it is possible to use a method for producing an internal combustion engine component having, on the surface thereof, a porous layer formed by three-dimensionally interconnected grains of a ferrite which is an iron oxide, the method comprising a step of causing a hydrothermal synthesis reaction of 1) a surface of a base material of the component or 2) a surface of a metallic layer which has been formed in advance on the surface of the base material of the component, and an aqueous solution or an aqueous dispersion containing an iron component, to form the porous layer on the surface (base material surface or metallic layer surface).

As described above, in the production method of the present invention, it is possible to form a porous layer directly on the surface of the base material of the component, and also to form a metallic layer in advance on the surface of the base material and then form a porous layer on the surface of the metallic layer. For example, in the case where the base material (such as a titanium alloy) does not include an iron component, a higher bonding strength can be obtained by forming a metallic layer in advance and then providing a porous layer. In the case of forming a metallic layer, the configuration and the production method described in section 1. hereinabove can be used to form the metallic layer.

In particular, (1) a treatment liquid including Fe or (2) a treatment liquid including Fe and at least one of Al, Mg, Mn and Zn can be used as the aqueous solution or aqueous dispersion (both of which are collectively referred to as treatment liquid) including an iron component, but these examples are not limiting.

The treatment liquid can be prepared, for example, by using a compound serving as a supply source of the iron component. For example, a metal salt, a metal oxide, a metal hydroxide, or the like can be used. As the metal salt, at least one of an inorganic acid salt and an organic acid salt can be used. As the inorganic acid salt, for example, a sulfate, a carbonate, a chloride and the like can be used. Further, as the organic acid salt, an acetate, an oxalate and the like can be used. Any of these water-solubilizable (water-soluble) or hardly water-soluble metal compounds can be used, but in the present invention, a water-soluble metal compound can be used particularly advantageously. The concentration of the metal component in the treatment liquid is not limited, and can be appropriately set according to the type of the metal component used, reaction conditions, and the like.

Further, in particular, an alkali can be advantageously added to the treatment liquid in order to accelerate the hydrothermal synthesis reaction of the ferrite film. The alkali is not particularly limited, and for example at least one of sodium hydroxide, potassium hydroxide and the like can be used. The molar ratio of the alkali to the total amount of metal ions in the treatment liquid in this case is usually 3.1 mol to 36 mol per 1 mol of the total amount of metal ions, the specific ratio depending on the type of the metal salt used and the like.

In the treatment liquid, each component such as metal salt, alkali and the like may be dissolved or partially dissolved in water. Further, the components also may be dispersed rather than dissolved (suspension (aqueous dispersion)).

The conditions of the hydrothermal synthesis reaction itself may be in accordance with known conditions of using the treatment liquid such as described above, but it is particularly preferable to carry out the hydrothermal synthesis reaction by the following method. Thus, it is preferable to use a method including, as the hydrothermal synthesis reaction, a step of performing heat treatment under an environment at or above a saturated water vapor pressure at 105° C. to 150° C. in a state in which 1) the surface of the base material of the component or 2) the surface of the metallic layer which has been formed in advance on the surface of the base material of the component, is in contact with a treatment liquid obtained by mixing a metal salt, an alkali, and water.

Further, in the present invention, the hydrothermal synthesis reaction can also be carried out in the presence of a reducing agent. As a result of using a reducing agent, the formation of trivalent iron ions in the reaction system is inhibited or prevented. As a consequence, it is possible to form the porous layer even more reliably. Therefore, the reducing agent is not limited and can be appropriately selected from known reducing agents as long as it can inhibit or prevent the formation of trivalent iron ions. For example, compounds known as antioxidants such as ascorbic acid and hydroquinones can be advantageously used. In the present invention, it is preferable that the reducing agent be included in advance in the treatment liquid (particularly, the reducing agent is dissolved in the treatment liquid).

The amount of the treatment liquid that is sufficient to form a predetermined porous layer may be used. Therefore, in the present invention, for example, a method of immersing a portion where a porous layer is to be formed in a treatment liquid can be advantageously used.

The conditions for performing a reaction with the treatment liquid are not particularly limited as long as the conditions ensure that ferrite which is an iron oxide can be produced. In particular, when performing a hydrothermal synthesis reaction as a reaction with the treatment liquid, it is preferable to perform heat treatment under an environment at or above a saturated water vapor pressure at 105° C. to 150° C. By performing heat treatment under such temperature and pressure, it is possible to form advantageously a predetermined porous layer. Such temperature/pressure conditions can be set, for example, by using a well-known device such as an autoclave device (sealed system).

Further, the time for reacting with the treatment liquid (the reaction time of the hydrothermal synthesis reaction) can be appropriately adjusted according to the desired thickness of the porous layer and the like. Thus, the reaction may be continued until the heat insulating film having the aforementioned preferable thickness is formed, but in order to obtain a porous layer of uniform thickness which has a desired thickness, the reaction is usually carried out for 16 h to 96 h in the case of hydrothermal synthesis reaction. When sufficient thickness of the porous layer cannot be obtained in one reaction cycle, a method of repeating the reaction a plurality of times may be used.

In the production method of the present invention, it is preferable that the ferrite described in section 1. hereinabove be formed as the porous layer. Therefore, it is preferable that an iron-based metal be used as the base material or the metallic layer. When an iron-based metal surface is immersed in the treatment liquid, the outermost surface (contact surface) of the base material or the metallic layer changes to iron hydroxide (Fe(OH)₂), the surface is further slightly dissolved, and the vicinity of the base material surface or of the metallic layer surface becomes rich in iron ions. Accordingly, by carrying out a hydrothermal synthesis reaction of the outermost surface of the base material or the metallic layer and the treatment liquid, it is possible to form advantageously a ferrite porous layer having excellent adhesion to the base material or the metallic layer. For example, in the case of producing iron ferrite (in the aforementioned case of x=0), according to the production method of the present invention, it is possible to produce ferrite from iron through the following stages 1) and 2).

Fe²⁺+2OH⁻→Fe(OH)₂ 1)

Fe(OH)₂→Fe₃O₄ 2)

As embodiments of the production method of the present invention, there are various variations depending on the layer configuration, and any of these is encompassed in the production method of the present invention. For example, in the case of hydrothermal synthesis reaction, the following methods can be used:

(a) a method including a step of forming a porous layer by a hydrothermal synthesis reaction as the upper layer of a base material of an internal combustion engine component; and (b) a method including a step of forming a metallic layer on the upper layer of the base material by a plating method or a sputtering method, and a step of forming a porous layer by a hydrothermal synthesis reaction on the surface of the metallic layer.

All these methods are encompasses in the production method of the present invention.

### Embodiment 1

A preferred embodiment of the present invention is an engine valve (valve of the present invention) having a porous layer formed by three-dimensional interconnection of grains of ferrite which is a spinel type iron oxide at least on the combustion surface of an valve head. In the engine valve, the combustion surface of the valve head becomes the surface exposed to the combustion chamber. Therefore, the porous layer is formed at least on the combustion surface of the valve head.

The shape of the valve of the present invention itself is the same as that of a known general engine valve as shown in FIG. 1 (reference numerals 5 and 6) or FIG. 2 (reference numerals 5 and 6), and a poppet valve with a conical distal end portion can be employed. The present invention is applicable not only to a solid type but also to a hollow valve.

The same materials as those of well-known valves can be used as the base material (material) of the engine valve main body. For example, nickel, titanium, iron, aluminum and the like, alloys thereof (for example, a titanium-based alloy, a nickel-based alloy, an aluminum-based alloy, stainless steel and the like) and the like can be used. In the present invention, as described above, the metallic layer can be also formed as needed according to the material properties of the base material or the like. Therefore, a porous layer excellent in adhesiveness can be advantageously formed regardless of the type of the base material or the like.

The porous layer can be formed on the entire combustion surface of the valve head or a part thereof, but in the present invention, it is desirable to form a porous layer on the entire combustion surface of the valve head. In particular, by forming a porous layer on the entire surface, higher heat insulating property can be obtained.

In general, valves used for engines include intake valves and exhaust valves, but any of the valves is included in the present invention. With respect to the intake valve 5, as shown in FIG. 2(a), it is desirable that the porous layer 21 be formed at least on the combustion surface 11 of the valve head. With respect to the exhaust valve 6, as shown in FIG. 2(b), it is desirable that the porous layer 21 be formed on each of 1) the combustion surface 12 of the valve head, 2) the fillet 16 of the valve head excluding the valve face 14, and 3) the upper head region 18 connected to the fillet 16 of the valve head. By forming a porous layer on those surfaces, it is possible to provide an engine with excellent thermal efficiency. The structure and composition of the porous layer in the engine valve, the method for forming the porous layer, and the like can be the same as explained hereinabove.

In particular, in the present invention, an engine valve having a porous layer formed by a hydrothermal synthesis reaction of the surface of the base material of a valve main body or the surface of a metallic layer formed in advance on the surface of the base material and an aqueous solution or an aqueous dispersion containing an iron component at least on the combustion surface of the valve head can be advantageously used. Such a porous layer has a structure formed of assembled ferrite dendritic clusters extending upward from the surface of the base material of the valve main body or the surface of the metallic film. Since the porous layer has such a structure formed of clusters, it is possible to exhibit particularly excellent deflection resistance. Further, at the same time, since it is a porous layer, excellent heat insulating properties can be obtained. Furthermore, since the porous layer is configured of a ferrite, excellent properties such as oxidation resistance, thermal shock resistance and the like can be exhibited. For example, an engine valve in which a nickel-based metallic layer, an iron-based metallic layer, and a ferrite-based porous layer are formed sequentially in the order of description at least on the combustion surface of the valve head can be advantageously used as the valve of the present invention.

Such a valve of the present invention can be used in the same manner as the usual engine valve. For example, the valve can be used for various engines such as automobile engines, motorcycle engines, marine engines and the like. Further, the valve can be used in any of gasoline engine, diesel engine and the like.

### EXAMPLES

Examples will be shown below and aspects of the present invention will be described more specifically. However, the scope of the present invention is not limited to the examples.

### Example 1

(1) Engine Valve Having a Porous Layer and Fabrication Thereof

(1-1) Structure of Engine Valve

An intake engine valve 5 having the configuration shown in FIG. 2(a) was produced. As for the size of the engine valve 5, the diameter of the valve head was 35.0 mm, the diameter of the valve stem was 5.5 mm, the length of the valve stem was 90.0 mm, and the length from the combustion surface of the valve head to the valve top of the valve stem was 113.2 mm.

As shown in FIG. 3, a porous layer 21 having a thickness of 70 μm was formed on the combustion surface 11 of the valve head of the engine valve 5, with a metallic layer 23 being interposed therebetween. The metallic layer was formed of two layers, namely, a nickel film (on the base material side) with a thickness of 1 μm and an iron film (on the porous layer side) with a thickness of 6 μm. The porous layer 21 was formed of a spinel type iron oxide (that is, iron ferrite) which was a black crystalline material. The ferrite grains were three-dimensionally interconnected.

(1-2) Production of Engine Valve

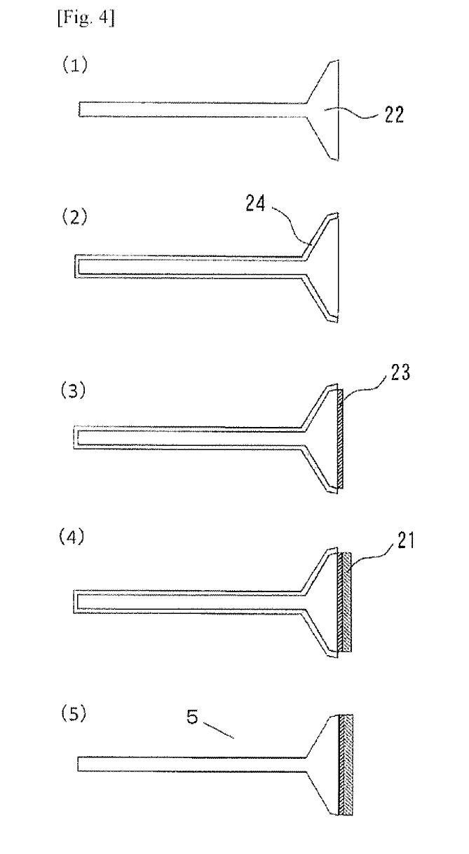

The engine valve 5 was fabricated according to the production process shown in FIG. 4. First, a heat-resistant stainless steel material (martensitic heat-resistant steel SUH11: carbon steel including chromium and silicon) was machined to prepare a base material 22 having the dimensions of the above-mentioned valve 5 (FIG. 4(1)). Only the combustion surface of the valve head of the base material 22 was left, and the surface of other portions was masked with the resin paint coating film 24 (FIG. 4(2)).

A metallic layer was formed on the combustion surface of the valve head by electroplating. First, a nickel plating film with a thickness of 1 μm was formed on the combustion surface of the valve head by a strike nickel plating, and immediately thereafter an iron plating film with a thickness of 6 μm was formed on the nickel plating film by an iron electroplating. In this way, a metallic layer 23 composed of two layers of a nickel plating film and an iron plating film was formed (FIG. 4(3)).

Subsequently, a porous ferrite film 21 having a thickness of 70 μm was formed on the surface of the metallic film 23 (that is, the surface of the iron plating film) of this sample (FIG. 4(4)). In this case, the method of forming the porous ferrite film on the surface was carried out as follows.

An aqueous solution prepared by dissolving 417 g (=1.5 mol) of ferrous sulfate (FeSO₄.7H₂O) in 800 mL of water prepared by distillation in nitrogen gas, and 400 mL of an aqueous solution of 216 g (=5.4 mol) of sodium hydroxide (NaOH) were mixed to prepare a suspension. In this suspension, the molar ratio of the alkali to the total amount of metal ions was 3.6 mol per 1 mol of metal ions.

Next, the suspension was poured into a cylindrical autoclave reaction vessel made of stainless steel and having an inner volume of 2 L. The sample was immersed into the suspension and fixed using a jig. The above operation was performed in a nitrogen gas atmosphere. By treating (hydrothermal treatment) in an autoclave reaction vessel at 120° C. for 44 hours, a hydrothermal synthesis reaction of the surface of the iron plating film of the sample with the suspension was performed. After the reaction time elapsed, the sample was taken out together with the jig and thoroughly washed with water. In this way, a black porous layer was formed. Thereafter, the production of the engine valve 5 which was the internal combustion engine component of this embodiment was completed by removing the resin paint coating film 24. Table 1 shows the composition of the treatment liquid and the conditions of the hydrothermal synthesis reaction.

(2) Material Analysis of Porous Layer

In order to check whether or not the desired porous layer was formed in the engine valve 5, two types of rectangular substrates (substrate A and substrate B) having a size of 50 mm in length×20 mm in width×0.5 mm in thickness and made of different materials were prepared.

The material of the substrate A was pure iron which was the same as the composition of the metallic layer (iron plating film) in contact with the porous layer. The substrate A was used for composition analysis and crystal structure analysis. The reason why a heat-resistant stainless steel (including nickel and other metal components such as chromium, in addition to iron), which is the material of the base material of the valve, was not used as the substrate, is to perform material analysis which is not affected by the material of the lower layer of the porous layer.

The material of the substrate B was the same material as the base material 22 (heat-resistant stainless steel in which a composite film of a nickel plating film and an iron plating film was formed as a metallic layer). The substrate B was used to measure the thickness of the layer formed on the surface and to observe the film formation.

In the same manner as in the case of the engine valve 5 described above, the substrate A and the substrate B were placed together with the base material of the engine valve in the treatment liquid in the same reaction vessel, and the substrate surfaces were simultaneously subjected to a hydrothermal synthesis reaction. In this way, two types of samples were prepared separately from the engine valve 5.

The layer formed on the substrate A (pure iron) was subjected to composition analysis using a fluorescent X-ray analyzer, and the crystal structure was examined by X-ray diffraction analysis with CuKα rays. As a result of the composition analysis, only iron was detected in the layer. The X-ray diffraction pattern is shown in FIG. 5. From the results shown in FIG. 5, it was revealed that the layer is a film formed of a crystal phase which can be identified as a spinel type iron oxide (=iron ferrite) Fe₃O₄ having a high crystallinity and a lattice constant a₀=8.40 Å.

The thickness of the porous layer was obtained by measuring the difference in thickness of the substrate B between before and after the formation of the porous layer. As a result, the thickness of the formed porous layer was 70 μm.

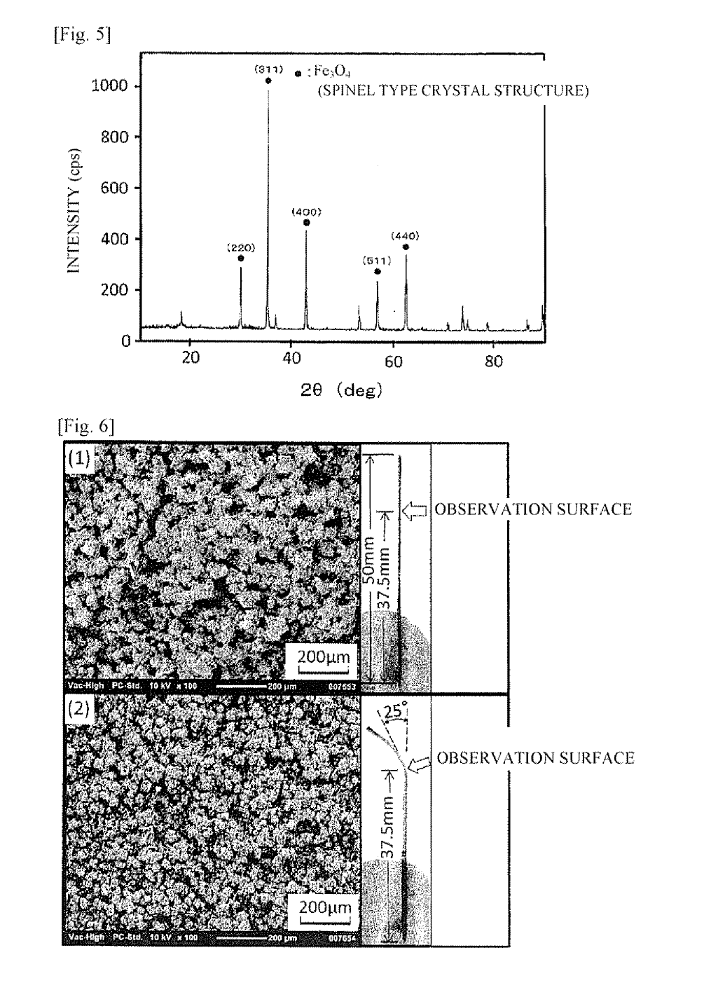

Further, the surface of the layer formed on the substrate B was observed as it was by using a scanning electron microscope (SEM). The substrate B was bent at an angle of about 25 degrees at a position of 37.5 mm from one end of a length of 50 mm, and the presence or absence of peeling of the layer from the substrate was investigated. No peeling was observed by visual observation. Further, the surface of the porous layer at the bent portion before and after the bending test was observed with a scanning electron microscope (SEM). The scanning electron microscope (SEM) images are shown in FIG. 6.

FIG. 6(1) shows the surface of the porous layer before the bending test, and FIG. 6(2) shows the surface of the porous layer after the bending test. It was revealed from the results shown in FIG. 6(1) that a porous layer formed of a plurality of similarly shaped crystal grains having different sizes is formed. Further, from the comparison between FIG. 6(1) and FIG. 6(2), it was revealed that even when the substrate is bent, the porous layer at the bent portion do not peel off from the substrate. Thus, the in-plane bonding portions in the porous layer between a large number of clusters constituting the porous layer were broken and the clusters in the surface of the porous layer was further divided into clusters having smaller size.

Further, in order to observe the shape of the cross section of the porous layer, another substrate B was prepared, the reaction vessel used for forming the porous layer on the engine valve 5 was used, the same treatment liquid was used, and a hydrothermal synthesis reaction was carried out at the same temperature of 120° C. for 88 hours to prepare a sample for cross section observation. Here, the reason for doubling the film formation time is to make the porous layer thick and facilitate the observation of the cross-sectional shape in the film growth direction from the metallic layer to the upper portion.

A transparent epoxy resin was poured into the resin cylindrical container (inner diameter 22 mm) in which the same sample was installed vertically, and the resin was cured to seal the sample with the resin. The substrate having a length of 50 mm was then cut into two at a position of 25 mm from one end of the substrate. The cross section was hand-polished using a #1000 polishing sheet. Furthermore, a very thin palladium film was formed by sputtering on the entire surface of the observation surface to ensure conductivity, thereby preparing a sample for cross-section observation. The cross section of this sample was observed with a scanning electron microscope (SEM). The SEM image is shown in FIG. 7.

From the result shown in FIG. 7, it was found that a porous film is formed of individual clusters (reference symbol “a” in FIG. 7) obtained by interconnection of grains in a dendritic manner upward from the surface of the metallic layer 23 disposed on the base material 22 of the substrate B. It was also found that a large space (a black region in FIG. 7) is formed between the clusters. Moreover, it is revealed that the pores formed between the clusters increase in size in the upward direction.

Thus, it appears that the crystal grains of iron oxide were generated on the surface of the metallic layer (the uppermost layer was a metallic iron film) and grew or increased upward, a plurality of ferrite crystal grains having nearly similar shape and variously different sizes was piled up to form one cluster, and a large number of voids were present between the clusters.

Because of such a structure, satisfactory deflection resistance is also exhibited. The reason therefor is not clear, but the following explanation can be suggested. During the formation of the porous layer, the adjacent clusters are weakly bonded (aggregated) to each other as the porous film grows. In this case, when a mechanical bending stress is applied to the base material, the weak bonding portion between the clusters is cut and the porous layer can synchronously follow the deflection of the base material, so that it is possible to prevent the base material of the porous layer from peeling off. This is apparently why satisfactory deflection resistance is exhibited.

From the material analysis results shown hereinabove, it was revealed that the layer obtained in this example has a porous structure with a density lower and heat capacity less than those of a ferrite ceramic sintered body (thermal conductivity is about 3.5 W·m⁻¹·K⁻¹ at 400° C.; volumetric specific heat 5.6 J·cm⁻³·K⁻¹ at 530° C.).

(3) Evaluation of Heat Insulating Property

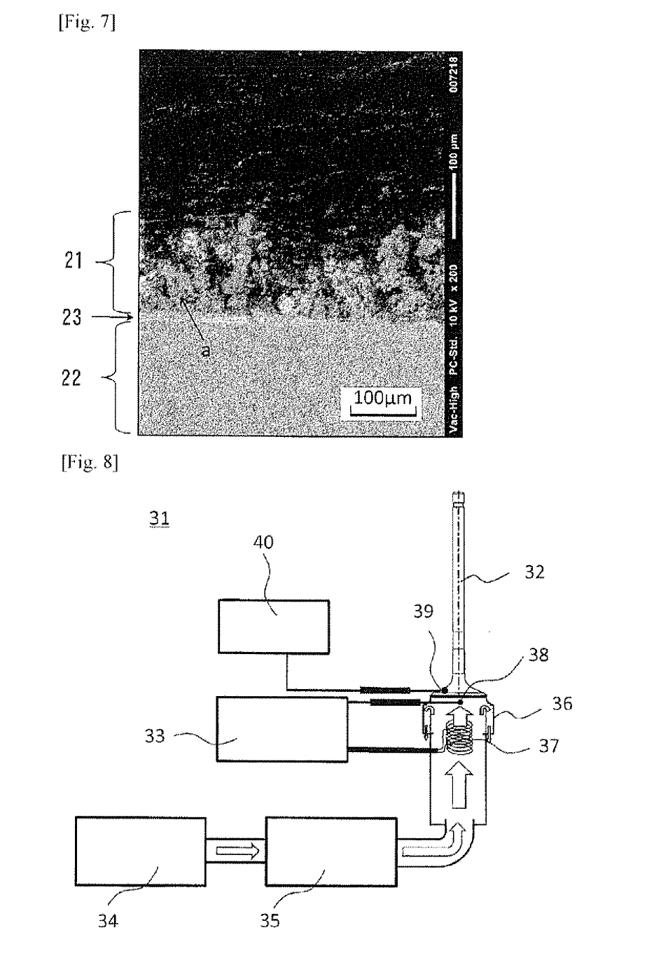

Heat insulating performance of the engine valve 5 was investigated by using a heat insulating property evaluating device 31 shown in FIG. 8 and comparing with thermal conductivity characteristic of the valve of the same shape which has no porous layer.

The device for evaluating the heat insulating property includes a test sample heating mechanism 36 for heating a valve 32 under test to a constant temperature while holding the valve, a heater controller 33, and an air flow rate controller 35 connected to an air compressor 34.

The test sample heating mechanism 36 has a structure capable of heating the combustion surface of the valve head of the valve 32 under test with hot air. A heater 37 is disposed directly below the combustion surface of the valve head of the valve 32 under test which is arranged for measurement. A temperature measuring portion of a thermocouple 38 for heater control is disposed at a position between the combustion surface of the valve head of the valve 32 under test and the heater 37. The heater controller 33 is operated by a temperature signal of the thermocouple 38 for heater control to control the power supplied to the heater 37. The air is caused to flow at a controlled flow rate from below the heater 37 and is converted into hot air of a set constant temperature to heat the combustion surface of the valve head of the valve 32 under test to a constant temperature. In the present example, the test was carried out by controlling the air flow rate to 25 liters per minute and setting the heating temperature of the combustion surface of the valve head of the valve 32 to 400° C.

A temperature measuring portion of a thermocouple 39 for temperature measurement is installed at a position where the thickness of the base material 22 is 3.5 mm from the combustion surface of the valve head of the valve 32. The measured surface temperature is recorded by a temperature recorder 40.

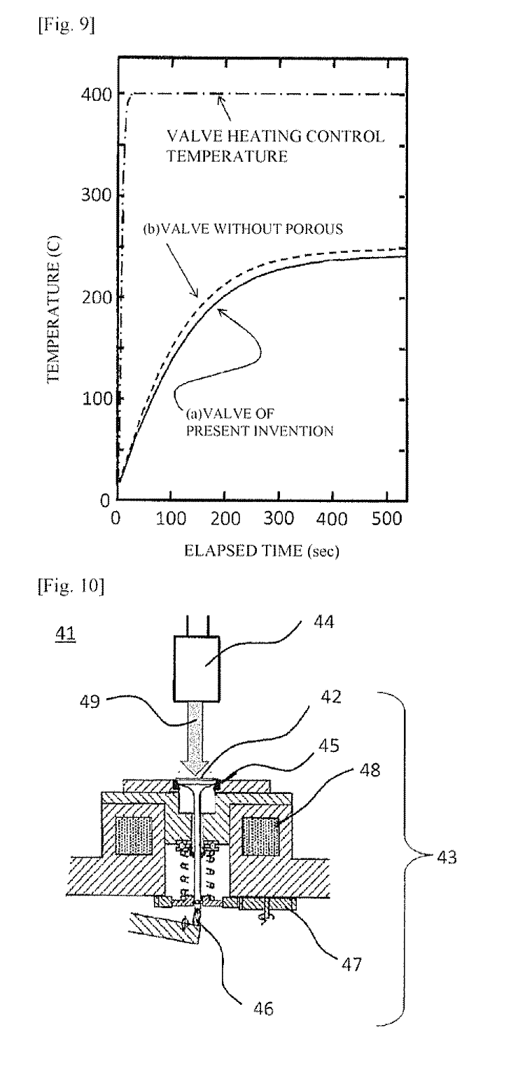

FIG. 9 shows the evaluation results of the heat insulating property. Here, the temperature on the fillet of the valve head of the valve 32 at a position where the thickness of the base material 22 is 3.5 mm from the combustion surface of the valve head, this temperature being recorded by the thermocouple 39 for temperature measurement, is plotted against the ordinate. The time elapsed from the start of heating of the fillet of the valve head of the valve 32 with hot air is plotted against the abscissa. The valve 5 (indicated by (a) in the figure) having the porous layer of the present example and the conventional valve (indicated by (b) in the figure) of the same shape which was measured for comparison were used as the valve 32 under test. In the same figure, the valve heating control temperature measured by the thermocouple 38 for heater control which was arranged to control the heater 37 is indicated by a dot-dash line.

As is apparent from FIG. 9, the temperature of the temperature measuring portion of the thermocouple disposed on the surface of the base material 22 on the outside air side of the porous layer 21 is lower than that of the valve without a porous layer. When the heating of the heater 37 starts, the valve heating control temperature, that is, the heating temperature of the combustion surface of the valve head of the valve 32 rapidly rises to 400° C. Following the temperature rise with a certain delay, the temperature of the fillet of the valve head of the valve 32 rises while drawing a gentle curve with respect to the elapsed time. At this time, the thermal energy provided to the combustion surface of the valve head by the hot air is conducted to the fillet of the valve head through the inside of the base material of the valve 32. Since the fillet of the valve head is cooled by the outside air at all times, the temperature of the fillet of the valve head is the equilibrium temperature of the fillet of the valve head at that point of time when the thermal energy conducted from the combustion surface of the valve head is released to the outside air. In the valve, since the transfer of the thermal energy transmitted to the base material 22 is inhibited by the porous layer 21, the amount of thermal energy transferred to the fillet of the valve head through the inside of the base material is reduced, so that the release to the outside air is inhibited. As a result, the temperature of the temperature measuring portion of the thermocouple disposed on the surface of the base material 22 on the outside air side of the porous layer 21 becomes lower than that of the valve without a porous layer.

Thus, it was found that in the component of the present invention (engine valve), it is possible to observe a temperature decrease of about 6° C. on the fillet of the valve head of the valve in a substantially equilibrium state 600 seconds after the start of heating as compared with the valve without a porous layer, thereby making it possible to exhibit superior thermal insulating performance.

(5) Evaluation of Durability

An accelerated test (durability test) was conducted to evaluate the durability of mechanical drive of the engine valve under high temperature atmosphere. As shown in FIG. 10, a durability test evaluation device 41 that was used is formed of a valve driving device 43 for installing a valve 42 under test and a combustion burner heating mechanism 44.

Further, the valve driving device 43 is provided with a water cooling mechanism 48 for cooling the driving portion of the device. In the valve driving device 43, the valve face of the valve 42 is arranged in a positional relationship such as to be in direct contact with the surface of a valve seat 45 in a stationary state. The valve 42 has a structure that is operated similar to a valve opening and closing operation in an engine by a valve lifting mechanism 46 and a valve rotating mechanism 47. Therefore, when the valve is driven, the environment is created in which the periphery of the valve head of the valve 42 in particular collides vigorously with the valve seat 45 which results in generation of mechanical strains. At the same time, the combustion surface of the valve head of the valve 42 is heated to a high temperature by a flame 49 ejected from the combustion burner heating mechanism 44. Thus, in the case of this example, since the porous layer is disposed on the entire combustion surface of the valve head, intermittent mechanical strains are generated in the porous layer on the combustion surface of the valve head in a high temperature atmosphere in this test. As a result, accelerated evaluation of durability against the peeling phenomenon of the porous layer which may occur in the engine can be performed.

The engine valve 5 having the aforementioned porous layer of this example was used as the valve under test 42. In the combustion burner heating mechanism 44, the combustion surface of the valve head was kept at a constant temperature of 400° C. by using a flame created by combustion of liquefied natural gas, and the durability test was conducted up to a total of 50 hours under test conditions of a valve vertical speed of 3000 rpm and a valve revolution speed of 20 rpm.

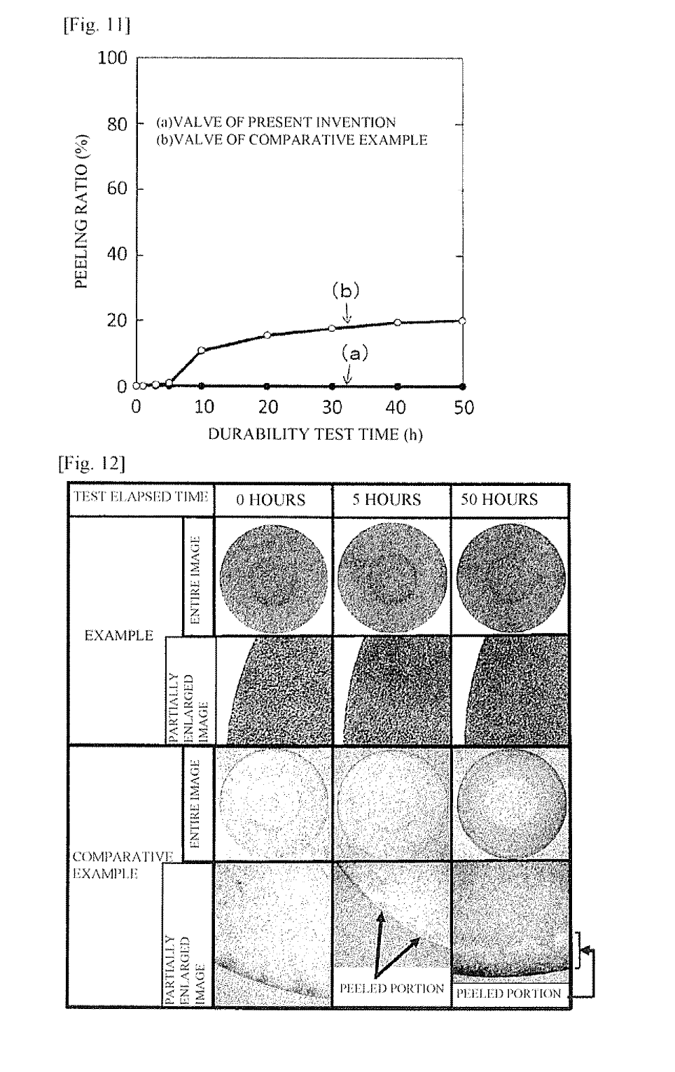

The evaluation was performed by temporarily stopping the operation of the durability test evaluation device 41 at the lapse of 1, 3, 5, 10, 20, 30, and 40 hours from the start of the operation of the durability test device, taking out the valve 42, cooling the valve to room temperature, and thereafter visually observing the peeling state of the porous layer (black) from the combustion surface of the valve head. Then, the valve 42 was again installed in the durability test evaluation device 41, and the operation was continued until the next observation time. The durability test was repeated until the total operation time reached 50 hours. In that case, the percentage of the area of the peeled portion to the total area of the surface of the porous layer was taken as the peeling ratio, and the peeling ratio was calculated for every elapsed time of the durability test (every 10 hours). The results are shown in Table 3 and FIG. 11. Further, a) the appearance of the porous layer before the test, b) the appearance after 5 hours in the course of the test, and c) the appearance after the last 50 hours have been observed. The results are shown in FIG. 12.

As Comparative Example 1, a valve having a zirconia sprayed film, which is the conventional porous layer material, was prepared and subjected to the same durability test. The valve of Comparative Example 1 was fabricated in the following manner. That is, a valve of the base material having the same material, shape and dimension as those used in Example 1 was prepared, and a metallic layer serving as a bonding layer formed of a thermally sprayed film of a nickel-chromium-aluminum-yttrium alloy and having a thickness of about 30 μm was formed by atmospheric plasma spraying method on the combustion surface of the valve head. Then, a zirconia film was overlayed and covered thereon with an average thickness of 100 μm by the same atmospheric plasma spraying method, thereby obtaining a valve of Comparative Example 1. The porous layer of the present example was a black ceramic film, whereas the zirconia sprayed film which was the porous layer of Comparative Example 1 was white. A durability test was carried out with respect to the obtained valve in the same manner as in Example 1. The results are shown in Table 4 and FIG. 11. In addition, changes in appearance of the porous layer were also observed in the same manner as in Example 1. The results are shown in FIG. 12.

In the valve (the valve of the present invention) of Example 1, peeling of the porous layer did not occur even after 50 hours of the durability test. By contrast, in the valve of Comparative Example 1 (the valve of the comparative example), after 5 hours of the durability test, as shown in FIG. 12, peeling started to occur slightly at the end of the periphery of the valve head of the valve where mechanical strains are most likely to be applied to the valve in the durability test. As shown in FIG. 12, the peeling progressed gradually from the end portion around the valve head toward the inside with the lapse of time of the durability test. After 50 hours, the peeling ratio reached 20%. From the above results, it was understood that the engine valve of Example 1 is excellent in durability.

TABLE 1

| | Treatment liquid | | | | | | | | | |
|---|---|---|---|---|---|---|---|---|---|---|
| | Metal salt liquid | | | | | | | | | |
| | (amount of water: 800 ml) | | | | | | | | | |
| | Metal salt | | | | | | | | | |
| | Main starting | | Additional | | | | Reducing | | Hydrothermal | |
| | material | | starting material | | Alkali liquid | | agent | | synthesis conditions | |
| | | Weight | | Weight | (amount of water: 400 ml) | | | Weight | Temperature | Time |
| | Type | (g) | Type | (g) | Type | Weight (g) | Type | (g) | (° C.) | (h) |
| Example 1 | Ferrous | 417 | — | — | Sodium | 216 | — | — | 120 | 44 |
| | sulfate | | | | hydroxide | | | | | |
| | (FeSO₄•7H₂0) | | | | (NaOH) | | | | | |
| Example 2 | Ferrous | 417 | — | — | Sodium | 216 | — | — | 120 | 44 |
| | sulfate | | | | hydroxide | | | | | |
| | (FeSO₄•7H₂0) | | | | (NaOH) | | | | | |
| Example 3 | Ferrous | 417 | — | — | Sodium | 216 | — | — | 120 | 136 |
| | sulfate | | | | hydroxide | | | | | |
| | (FeSO₄•7H₂0) | | | | (NaOH) | | | | | |
| Example 4 | Ferrous | 417 | — | — | Sodium | 216 | — | — | 120 | 204 |
| | sulfate | | | | hydroxide | | | | | |
| | (FeSO₄•7H₂0) | | | | (NaOH) | | | | | |
| Example 5 | Ferrous | 334 | Aluminum | 95 | Sodium | 216 | — | — | 120 | 68 |
| | sulfate | | sulfate | | hydroxide | | | | | |
| | (FeSO₄•7H₂0) | | (Al₂(SO₄)₃•16H₂O) | | (NaOH) | | | | | |
| Example 6 | Ferrous | 334 | Magnesium | 74 | Sodium | 216 | — | — | 150 | 72 |
| | sulfate | | sulfate | | hydroxide | | | | | |
| | (FeSO₄•7H₂0) | | (MgSO₄•7H₂O) | | (NaOH) | | | | | |
| Example 7 | Ferrous | 334 | Manganese | 72 | Sodium | 216 | — | — | 135 | 95 |
| | sulfate | | sulfate | | hydroxide | | | | | |
| | (FeSO₄•7H₂0) | | (MnSO₄•5H₂O) | | (NaOH) | | | | | |

TABLE 2

| | Treatment liquid | | | | | | | | | |
|---|---|---|---|---|---|---|---|---|---|---|
| | Metal salt liquid | | | | | | | | | |
| | (amount of water: 800 ml) | | | | | | | | | |
| | Metal salt | | | | | | | | | |
| | Main starting | | Additional | | | | | | Hydrothermal | |
| | material | | starting material | | Alkali liquid | | Reducing agent | | synthesis conditions | |
| | | Weight | | Weight | (amount of water: 400 ml) | | | Weight | Temperature | Time |
| | Type | (g) | Type | (g) | Type | Weight (g) | Type | (g) | (° C.) | (h) |
| Example 8 | Ferrous | 334 | Zinc | 86 | Sodium | 216 | — | — | 150 | 16 |
| | sulfate | | sulfate | | hydroxide | | | | | |
| | (FeSO₄•7H₂0) | | (ZnSO₄•7H₂O) | | (NaOH) | | | | | |
| Example 9 | Ferrous | 42 | — | — | Sodium | 216 | Ascorbic | 2 | 120 | 44 |
| | sulfate | | | | hydroxide | | acid | | | |
| | (FeSO₄•7H₂0) | | | | (NaOH) | | | | | |
| Example | Ferrous | 417 | — | — | Sodium | 216 | — | — | 105 | 68 |
| 10 | sulfate | | | | hydroxide | | | | | |
| | (FeSO₄•7H₂0) | | | | (NaOH) | | | | | |
| Example | Ferrous | 298 | — | — | Sodium | 216 | — | — | 120 | 68 |
| 11 | chloride | | | | hydroxide | | | | | |
| | (FeCl₂•4H₂0 | | | | (NaOH) | | | | | |
| Example | Ferrous | 487 | — | — | Sodium | 216 | Ascorbic | 5 | 120 | 48 |
| 12 | sulfate | | | | hydroxide | | acid | | | |
| | (FeSO₄•7H₂0) | | | | (NaOH) | | | | | |
| Example | Ferrous | 417 | — | — | Sodium | 216 | — | — | 120 | 48 |
| 13 | sulfate | | | | hydroxide | | | | | |
| | (FeSO₄•7H₂0) | | | | (NaOH) | | | | | |
| Example | Ferrous | 417 | — | — | Sodium | 216 | — | — | 120 | 48 |
| 14 | sulfate | | | | hydroxide | | | | | |
| | (FeSO₄•7H₂0) | | | | (NaOH) | | | | | |

TABLE 3

| | | Metallic layer | | | | Porous layer | | Peeling |
|---|---|---|---|---|---|---|---|---|
| | | Layer on base material side | | Layer on porous layer side | | Metal | | ratio after |
| | Base | | Thickness | | Thickness | elements in | Thickness | durability |
| | material | Composition | (μm) | Composition | (μm) | composition | (μm) | test (%) |
| Example 1 | Heat- | Ni | 1 | Fe | 6 | Fe | 70 | 0 |
| | resistant | | | | | | | |
| | stainless | | | | | | | |
| | steel | | | | | | | |
| Example 2 | Heat- | Ni | 1 | Fe | 4 | Fe | 70 | 0 |
| | resistant | | | | | | | |
| | stainless | | | | | | | |
| | steel with | | | | | | | |
| | nitrided | | | | | | | |
| | surface | | | | | | | |
| Example 3 | Heat- | Ni | 1 | Fe | 6 | Fe | 230 | 0 |
| | resistant | | | | | | | |
| | stainless | | | | | | | |
| | steel | | | | | | | |
| Example 4 | Heat- | Ni | 1 | Fe | 6 | Fe | 350 | 0 |
| | resistant | | | | | | | |
| | stainless | | | | | | | |
| | steel | | | | | | | |
| Example 5 | Heat- | Ni | 1 | Fe | 6 | Fe, Al | 40 | 0 |
| | resistant | | | | | | | |
| | stainless | | | | | | | |
| | steel | | | | | | | |
| Example 6 | Heat- | Ni | 1 | Fe | 6 | Fe, Mg | 75 | 0 |
| | resistant | | | | | | | |
| | stainless | | | | | | | |
| | steel | | | | | | | |
| Example 7 | Heat- | Ni | 1 | Fe | 6 | Fe, Mn | 75 | 0 |
| | resistant | | | | | | | |
| | stainless | | | | | | | |
| | steel | | | | | | | |

TABLE 4

| | | Metallic layer | | | | Porous layer | | Peeling |
|---|---|---|---|---|---|---|---|---|
| | | Layer on base material side | | Layer on porous layer side | | Metal | | ratio after |
| | Base | | Thickness | | Thickness | elements in | Thickness | durability |
| | material | Composition | (μm) | Composition | (μm) | composition | (μm) | test (%) |
| Example 8 | Heat- | Ni | 1 | Fe | 6 | Fe, Zn | 65 | 0 |
| | resistant | | | | | | | |
| | stainless | | | | | | | |
| | steel | | | | | | | |
| Example 9 | Heat- | Ni | 1 | Fe | 10 | Fe | 65 | 0 |
| | resistant | | | | | | | |
| | stainless | | | | | | | |
| | steel with | | | | | | | |
| | nitrided | | | | | | | |
| | surtace | | | | | | | |
| Example 10 | Heat- | Ni | 1 | Fe | 6 | Fe | 40 | 0 |
| | resistant | | | | | | | |
| | stainless | | | | | | | |
| | steel | | | | | | | |
| Example 11 | Heat- | Ni | 0.5 | Fe | 6 | Fe | 115 | 0 |
| | resistant | | | | | | | |
| | stainless | | | | | | | |
| | steel | | | | | | | |

| Example 12 | Heat- | Composition | Thickness (μm) | Fe | 80 | 0 |
|---|---|---|---|---|---|---|
| | resistant | Fe | 4 | | | |
| | stainless | | | | | |
| | steel | | | | | |
| Example 13 | Carbon steel | — | | Fe | 80 | 0 |
| | (iron) | | | | | |
| Example 14 | Cast iron | — | | Fe | 80 | — |
| | (iron) | | | | | |
| Comparative | Heat- | Ni, Cr, Al, Y | 30 | Zr, Y | 100 | 20 |
| Example 1 | resistant | | | | | |
| | stainless | | | | | |
| | steel | | | | | |

### Example 2

(1) Engine Valve Having a Porous Layer and Fabrication Thereof

The internal combustion engine component having a porous layer of this example is an exhaust engine valve 6 having the configuration shown in FIG. 2(b). The diameter of the valve head is 29.0 mm, the diameter of the valve stem is 5, 5 mm, the length of the valve stem is 80.0 mm, and the distance from the combustion surface of the valve head to the valve top of the valve stem is 105.8 mm. The base material 22 constituting the valve 6 is a heat-resistant stainless steel (austenitic heat-resistant steel SUH 35: carbon steel containing chromium, nickel and manganese) having a black-gray nitride film formed on the entire surface thereof by nitriding treatment.

As shown in FIG. 2(b), the porous layer 21 formed of a porous film of iron ferrite having a thickness of 70 μm was formed on surfaces of the base material 22 subjected to the nitriding treatment, that is, on the combustion surface 12 of the valve head, the fillet 16 of the valve head excluding the valve face 14, and the upper head region 18 connected to the fillet 16 of the valve head, of the valve 6 of this Example 2. The metallic film 23 formed of two layers, namely, a nickel film (base material side) having a thickness of 1 μm and an iron film (porous layer side) having a thickness of 4 μm was interposed between the porous layer and the base material, in the same manner as in Example 1.

The valve was produced in the same manner as in Example 1 as shown in FIG. 4. In this case, in the step shown in FIG. 4(2), only the portion coated with the resin paint coating film 24 was different. Specifically, the valve face 14 was produced on the face portion by forming a porous layer, without coating with the resin paint coating film 24, and then removing the porous layer by machining.

First, a heat resistant stainless steel having a nitrided coating film was used as the base material 22, the surface thereof was cleaned with an alkali cleaning liquid, and then sufficiently washed with water. Thereafter, it was confirmed that there is no peeled portion in the nitrided film, and it has electric conductivity at the same time. Next, the above-mentioned portion was covered with the resin paint coating film 24. Thereafter, in the same manner as in Example 1, a nickel plating film with a thickness of 1 μm was formed by electroplating on the surface of the base material 22, and an iron plating film with a thickness of 4 μm was immediately formed thereon, thereby forming the metallic layer 23 formed of two layers, namely, the nickel plating film and the iron plating film. Subsequently, the porous layer 21 having a thickness of 70 μm was formed in the same manner as in Example 1. The treatment liquid composition and hydrothermal synthesis conditions of this example are shown in Table 1.

(2) Material Analysis of Porous Layer

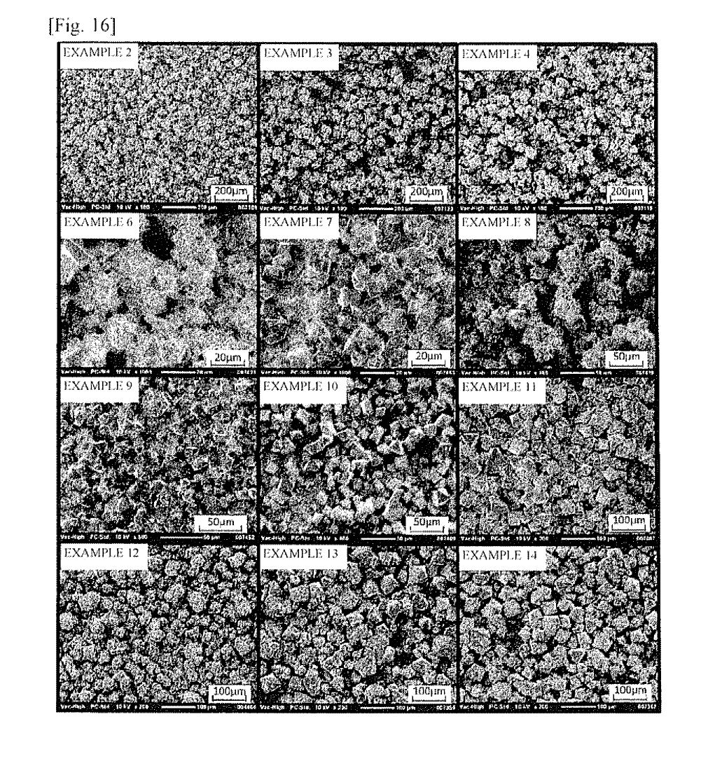

The material analysis of the obtained porous layer 21 was carried out in the same manner as in “(2) Material analysis of porous layer” of Example 1. The results confirmed that the porous layer 21 of the present example was a porous film same as that in Example 1 and that the film was formed of a crystal phase which was identified as a ferrite having a high crystallinity and a spinel type crystal structure with a lattice constant a₀=8.40 Å. Further, the SEM image of the surface of the porous layer 21 of this example is shown in FIG. 16.

(3) Evaluation of Durability

A durability test was carried out in the same manner as in “(5) Evaluation of durability” of Example 1. The results are shown in Table 3. It is apparent from these results that, as in Example 1, peeling of the porous layer was not observed even after 50 hours of the durability test.

### Example 3

(1) Engine Valve Having a Porous Layer and Fabrication Thereof

An engine valve was fabricated in the same manner as in Example 1 except that the thickness of the porous layer was set to 230 μm. A hydrothermal synthesis reaction was carried out for 68 hours at 120° C. by using a suspension having the same composition as in Example 1 as a treatment liquid. After the lapse of the reaction time, the base material was taken out together with the jig and thoroughly washed with water in order to separate the base material from the powder compound of the reaction residue formed at the same time. In this way, a black porous ferrite film having a thickness of 110 μm was formed. The inside of the container was also likewise washed with water to remove the reaction residues which were formed thereon. Thereafter, the treatment liquid having the same amount as the above was prepared again, the base material was attached again together with the jig, hydrothermal synthesis reaction was carried out for 68 hours (total hydrothermal synthesis reaction time was 136 hours) at 120° C., and a porous layer having a thickness of 230 μm was formed. The treatment liquid composition and hydrothermal synthesis conditions of this example are shown in Table 1.

(2) Material Analysis of Porous Layer

The material analysis of the obtained porous layer was carried out in the same manner as in “(2) Material analysis of porous layer” of Example 1. The results confirmed that the porous layer of the present example was a porous film same as that in Example 1 and that the film was made of iron ferrite having high crystallinity and a spinel type crystal structure with a lattice constant a₀=8.40 Å. Further, the SEM image of the surface of the porous layer 21 of this example is shown in FIG. 16.

(3) Evaluation of Durability

A durability test was carried out in the same manner as in “(5) Evaluation of durability” of Example 1. The results are shown in Table 2. It is apparent from these results that, as in Example 1, peeling of the porous layer was not observed even after 50 hours of the durability test.

### Example 4

(1) Engine Valve Having a Porous Layer and Fabrication Thereof

The internal combustion engine component having the porous layer of this example is the engine valve 5 having exactly the same shape as in Example 1 except that the thickness of the porous layer is 350 μm. The porous layer 21 of the present example was formed by repeating twice the hydrothermal synthesis reaction for 68 hours at 120° C. in the same manner as in Example 2, and then conducting once the reaction for 68 hours at 120° C. by using the treatment liquid of the same composition (the total time of the hydrothermal synthesis reaction was 204 hours). The treatment liquid composition and hydrothermal synthesis conditions of this example are shown in Table 1.

(2) Material Analysis of Porous Layer

The material analysis of the obtained porous layer 21 was carried out in the same manner as in “(2) Material analysis of porous layer” of Example 1. The results confirmed that the porous layer of the present example is a porous film similar to that in Example 1 and that the film is made of iron ferrite having excellent crystallinity and a spinel type crystal structure with a lattice constant a₀=8.40 Å. The scanning electron microscopic (SEM) image of the surface of the porous layer 21 of this example is shown in FIG. 16.

(3) Evaluation of Durability

A durability test was carried out in the same manner as in “(5) Evaluation of durability” of Example 1. The results are shown in Table 3. It was apparent from these results that, as in Example 1, peeling of the porous layer is not observed even after 50 hours of the durability test.

### Example 5

(1) Engine Valve Having a Porous Layer and Fabrication Thereof

In the case of a ferrite ceramic material composition in which part of the iron component is substituted with another metal component, thermal conductivity does not depend on the type of the substitutional ion, but in addition to the ability of preventing the film peeling caused by the crystal structure change in a high-temperature oxidizing atmosphere, material properties such as coefficient of thermal expansion can be changed. For this reason, the formation of a substituted ferrite film having a composite composition as a porous layer of an internal combustion engine component is of important significance. Accordingly, porous layers each made of a ferrite material of composite composition, that is, porous layers of substituted ferrite obtained by substituting some of iron ions forming spinel type iron oxide Fe₃O₄ with various kinds of metal ions were produced.

In this example, an engine valve having a porous layer of an aluminum ferrite in which the substitute ions were aluminum ions was fabricated. The engine valve 5 has the same shape as that of Example 1. The difference from Example 1 is that the porous layer is a porous film of an aluminum ferrite having a thickness of 40 μm.

The fabrication method was the same as in Example 1 except that the composition of the treatment liquid was different. A suspension obtained by mixing an aqueous solution prepared by dissolving 334 g (=1.2 mol) of ferrous sulfate (FeSO₄.7H₂O) and 95 g (=0.15 mol) of aluminum sulfate (Al₂(SO₄)₃.16H₂O) in 800 ml of water and an alkaline aqueous solution prepared by dissolving 216 g of sodium hydroxide (NaOH) in 400 ml of water was used as the treatment liquid. At this time, the molar ratio of alkali to the total amount of metal ions in the treatment liquid was 3.6. Using the same reaction vessel as in Example 1, a sample in which a metallic layer 23 formed of a composite film of a nickel film (on the base material side) having a thickness of 1 μm and an iron film (on the porous layer side) having a thickness of 6 μm was formed in advance on the combustion surface of the valve head was immersed in the treatment liquid and subjected to a hydrothermal synthesis reaction at 120° C. for 60 hours. As a result, a black porous layer having a thickness of 40 μm was formed on the surface of the base material. The treatment liquid composition and hydrothermal synthesis conditions of this example are shown in Table 1.

(2) Material Analysis of Porous Layer

The material analysis of the obtained porous layer was carried out in the same manner as in “(2) Material analysis of porous layer” of Example 1. However, since the component (iron) of the base material was also added as a composition analysis value at the time of fluorescent X-ray composition analysis because the base material as the substrate consisted of a pure iron material, it was difficult to quantify the accurate composition of the ferrite film. Thus, only the qualitative analysis of the composition as to whether or not the substituted metal ions were contained in the ferrite composition was carried out.

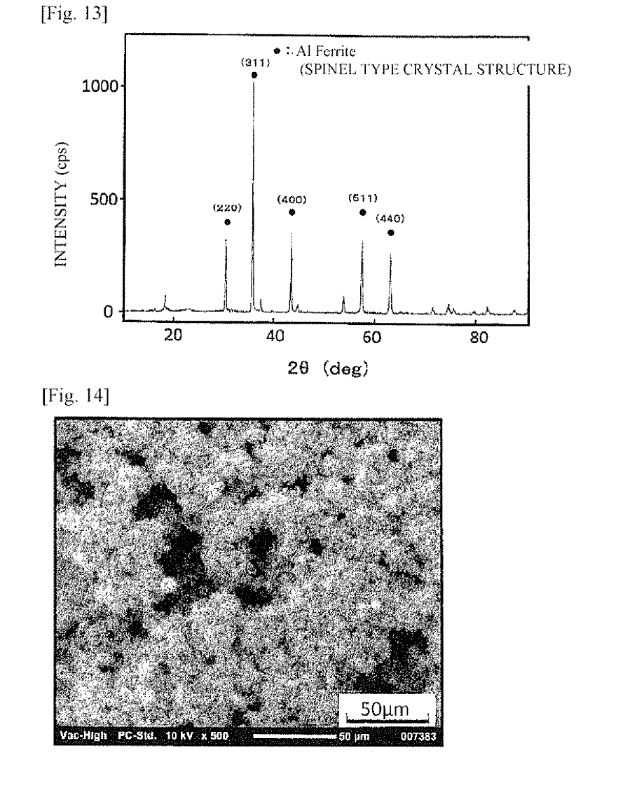

As a result, a compound of iron and aluminum was confirmed. Further, the crystal structure was also examined by X-ray diffraction analysis. The X-ray diffraction pattern is shown in FIG. 13. The results confirmed that the film is made only of ferrite having a very high crystallinity and a spinel type crystal structure with a lattice constant a₀=8.35 Å. That is, it was found that the formed porous layer is aluminum ferrite.

The SEM image of the surface of the obtained porous layer is shown in FIG. 14. Compared with Example 1, the crystal grain size is smaller by about one order of magnitude or more, but it was revealed that the porous body is of the same form as in Example 1 and has a structure formed by a plurality of crystal grains of similar shape and different in size which is piled up and joined together to be three-dimensionally interconnected.

(3) Evaluation of Durability

A durability test was carried out in the same manner as in “(5) Evaluation of durability” of Example 1. The results are shown in Table 3. It is apparent from these results that, as in Example 1, peeling of the porous layer was not observed even after 50 hours of the durability test.

### Example 6

(1) Engine Valve Having a Porous Layer and Fabrication Thereof

In this example, an engine valve having a porous layer of magnesium ferrite in which the substitute ion was magnesium ion was manufactured.

The fabrication method was the same as in Example 5 except for the following aspect. A suspension obtained by mixing an aqueous solution prepared by dissolving 334 g (=1.2 mol) of ferrous sulfate (FeSO₄.7H₂O) and 74 g (=0.3 mol) of magnesium sulfate (MgSO₄.7H₂O) in 800 ml of water and an alkaline aqueous solution prepared by dissolving 216 g of sodium hydroxide (NaOH) in 400 ml of water was used as the treatment liquid. At this time, the molar ratio of alkali to the total amount of metal ions in the treatment liquid was 3.6. A hydrothermal synthesis reaction was conducted for 72 hours at 150° C. As a result, a black film having a thickness of 75 μm was obtained as the porous layer. The treatment liquid composition and hydrothermal synthesis conditions of this example are shown in Table 1.

(2) Material Analysis of Porous Layer

The material analysis of the obtained porous layer 21 was carried out in the same manner as in “(2) Material analysis of porous layer” of Example 1. As a result, it was found that the obtained black film consisted only of a compound formed of iron and magnesium and had a very high crystallinity and a spinel type crystal structure with a lattice constant a₀=8.36 Å. That is, it was confirmed that the formed porous layer is magnesium ferrite. It was found that the porous layer is a porous body in which an average grain size is smaller than that of Example 1, but the form is similar to that of Example 1, and the porous body is formed by three-dimensional interconnection of clusters in which a plurality of similarly shaped crystal grains differing in size is joined in a piled-up state. The SEM image of the surface of the porous layer 21 of this example is shown in FIG. 16.

(3) Evaluation of Durability

A durability test was carried out in the same manner as in “(5) Evaluation of durability” of Example 1. The results are shown in Table 3. It was apparent from these results that, as in Example 1, peeling of the porous layer is not observed even after 50 hours of the durability test.

### Example 7

(1) Engine Valve Having a Porous Layer and Fabrication Thereof

In this example, an engine valve having a porous layer of manganese ferrite in which the substitute ion was manganese ion was fabricated in the same manner as in Example 5.

The production method was the same as in Example 5 except for the following aspect. A suspension obtained by mixing an aqueous solution prepared by dissolving 334 g (=1.2 mol) of ferrous sulfate (FeSO₄.7H₂O) and 72 g (=0.32 mol) of manganese sulfate (MnSO₄.5H₂O) in 800 ml of water and an alkaline aqueous solution prepared by dissolving 216 g of sodium hydroxide (NaOH) in 400 ml of water was used as the treatment liquid. At this time, the molar ratio of alkali to the total amount of metal ions in the suspension was 3.55. A hydrothermal synthesis reaction was conducted for 95 hours at 135° C. A black porous layer having a thickness of 75 μm was thus formed. The treatment liquid composition and hydrothermal synthesis conditions of this example are shown in Table 1.

(2) Material Analysis of Porous Layer

The material analysis of the obtained porous layer 21 was carried out in the same manner as in “(2) Material analysis of porous layer” of Example 1. As a result, it was confirmed that the obtained black film was made only of manganese ferrite having a very high crystallinity and a spinel type crystal structure with a lattice constant a₀=8.41 Å. It was found that the average grain size is small, similar to Example 6, but the form is similar to that of Example 1, and the porous film is formed by three-dimensional interconnection of clusters in which a plurality of similarly shaped crystal grains differing in size is joined in a piled-up state. The SEM image of the surface of the porous layer 21 of this example is shown in FIG. 16.

(3) Evaluation of Durability

A durability test was carried out in the same manner as in “(5) Evaluation of durability” of Example 1. The results are shown in Table 3. It is apparent from these results that, as in Example 1, peeling of the porous layer was not observed even after 50 hours of the durability test.

### Example 8

(1) Engine Valve Having a Porous Layer and Fabrication Thereof

In this example, an engine valve having a porous layer of zinc ferrite in which the substitute ion was zinc ion was fabricated in the same manner as in Example 5.

The fabrication method was the same as in Example 5 except for the following aspect. A suspension obtained by mixing an aqueous solution prepared by dissolving 334 g (=1.2 mol) of ferrous sulfate (FeSO₄.7H₂O) and 86 g (=0.3 mol) of zinc sulfate (ZnSO₄.7H₂O) in 800 ml of water and an alkaline aqueous solution prepared by dissolving 216 g of sodium hydroxide (NaOH) in 400 ml of water was used as the treatment liquid. At this time, the molar ratio of alkali to the total amount of metal ions in the treatment liquid was 3.6. A hydrothermal synthesis reaction was conducted for 16 hours at 150° C. A black porous layer having a thickness of 65 μm was thus formed. The treatment liquid composition and hydrothermal synthesis conditions of this example are shown in Table 2.

(2) Material Analysis of Porous Layer

The material analysis of the obtained porous layer 21 was carried out in the same manner as in “(2) Material analysis of porous layer” of Example 1. As a result, it was confirmed that the obtained black film is made only of zinc ferrite having a very high crystallinity and a spinel type crystal structure with a lattice constant a₀=8.39 Å. It was found that the porous layer has a form similar to that of Example 1 and is a porous film formed by three-dimensional interconnection of clusters in which a plurality of similarly shaped crystal grains differing in size is joined with one another in a deposited state. The SEM image of the surface of the porous layer 21 of this example is shown in FIG. 16.

(3) Evaluation of Durability

A durability test was carried out in the same manner as in “(5) Evaluation of durability” of Example 1. The results are shown in Table 4. It was apparent from these results that, as in Example 1, peeling of the porous layer is not found even after 50 hours of the durability test.

### Example 9

(1) Engine Valve Having a Porous Layer and Fabrication Thereof

In this example, an engine valve having a porous layer of iron ferrite was prepared under a synthesis condition in which the concentration of iron sulfate in the treatment liquid was lower than that in Example 1. Another difference was that a heat resistant stainless steel in which a black-gray nitride film was formed in advance on the entire surface by nitriding was used as the base material 22.

The fabrication method was the same as in Example 1 except for the following aspect. In the metallic layer of the two-layer composite film, the metallic layer on the porous layer side was an iron plating film with a thickness of 10 μm and the composition of the treatment liquid used was different. A suspension obtained by mixing an aqueous solution prepared by dissolving 42 g (=0.15 mol) of ferrous sulfate (FeSO₄.7H₂O) and 2 g of ascorbic acid in 800 ml of water and an alkaline aqueous solution prepared by dissolving 216 g of sodium hydroxide (NaOH) in 400 ml of water was used as the treatment liquid. The molar ratio of alkali to the total amount of metal ions in the treatment liquid in this example was 36. A hydrothermal synthesis reaction was conducted in the same manner as in Example 1, and a black porous film having a thickness of 65 μm was formed. The treatment liquid composition and hydrothermal synthesis conditions are shown in Table 2.

(2) Material Analysis of Porous Layer

The material analysis of the obtained porous layer 21 was carried out in the same manner as in “(2) Material analysis of porous layer” of Example 1. The results showed that the film is a porous film of the same form as in Example 1 which is iron ferrite having a very high crystallinity and a spinel type crystal structure with a lattice constant a₀=8.40 Å. The SEM image of the surface of the porous layer 21 of this example is shown in FIG. 16.

(3) Evaluation of Durability

A durability test was carried out in the same manner as in “(5) Evaluation of durability” of Example 1. The results are shown in Table 4. It is apparent from these results that, as in Example 1, peeling of the porous layer is not observed even after 50 hours of the durability test.

### Example 10

(1) Engine Valve Having a Porous Layer and Fabrication Thereof

The engine valve 5 was produced in the same manner as in Example 1 except that the thickness of the porous layer was 40 μm.

The formation of the porous layer 21 of this example was carried out in the same manner as in Example 1, except that the conditions of the hydrothermal synthesis reaction were set to 68 hours at 105° C. In this way, a black porous layer having a thickness of 40 μm was formed. The treatment liquid composition and hydrothermal synthesis conditions are shown in Table 2.

(2) Material Analysis of Porous Layer

The material analysis of the obtained porous layer 21 was carried out in the same manner as in “(2) Material analysis of porous layer” of Example 1. The results showed that the obtained black film is made only of iron ferrite having a very high crystallinity and a spinel type crystal structure with a lattice constant a₃=8.40 Å. It was found that the porous layer of the present example is a porous film of the form similar to that in Example 1. The SEM image of the surface of the porous layer 21 of this example is shown in FIG. 16.

(3) Evaluation of Durability

A durability test was carried out in the same manner as in “(5) Evaluation of durability” of Example 1. The results are shown in Table 4. It was apparent from these results that, as in Example 1, peeling of the porous layer is not found even after 50 hours of the durability test.

### Example 11

(1) Engine Valve Having a Porous Layer and Fabrication Thereof

An engine valve having a porous layer was fabricated. The fabrication method was the same as in Example 1 except for the following points. First, the difference from Example 1 was that in the two-layer composite metallic layer of the sample, the metallic layer on the base material side was a nickel plating film with a thickness of 0.5 μm. Such a sample was subjected to a hydrothermal synthesis reaction. A suspension obtained by mixing an aqueous solution prepared by dissolving 298 g (=1.5 mol) of ferrous chloride (FeCl₂.4H₂O) in 800 ml of water and an alkaline aqueous solution prepared by dissolving 216 g of sodium hydroxide (NaOH) in 400 ml of water was used as the treatment liquid. The molar ratio of alkali to the total amount of metal ions in the treatment liquid in this example was 3.6. A hydrothermal synthesis reaction was conducted for 68 hours at 120° C. A black porous film having a thickness of 115 μm was thus obtained. The treatment liquid composition and hydrothermal synthesis conditions are shown in Table 2.

(2) Material Analysis of Porous Layer

The material analysis of the obtained porous layer 21 was carried out in the same manner as in “(2) Material analysis of porous layer” of Example 1. The results showed that the black film is iron ferrite having a very high crystallinity and a spinel type crystal structure with a lattice constant a₀=8.40 Å. The black film was a porous film of the same form as that in Example 1. The SEM image of the surface of the porous layer 21 of this example is shown in FIG. 16.

(3) Evaluation of Durability

A durability test was carried out in the same manner as in “(5) Evaluation of durability” of Example 1. The results are shown in Table 4. It was revealed from these results that, as in Example 1, peeling of the porous layer is not observed even after 50 hours of the durability test.

### Example 12

(1) Engine Valve Having a Porous Layer and Fabrication Thereof

An engine valve similar to that of Example 1 was fabricated except that the metallic layer 23 was a single-layer iron film formed by sputtering and having a thickness of 4 pin and that the thickness of the porous layer was 80 μm.

A metallic iron film was formed as the metallic layer 23 by a sputtering method on the surface of the base material 22. The device used for the sputtering method was a high-frequency magnetron sputtering device with a reverse sputtering function capable of accommodating a 6-inch diameter target. In a sputtering device equipped with a target of metal iron, the base material 22 which had been resin-masked in advance except for the formation location of an iron film was attached to a substrate holder, and heated for 1 hour at 100° C. under vacuum evacuation. Then, the surface where a sputtered film had to be formed was subjected to reverse sputtering at a degree of vacuum of 8 Pa by using argon gas as a sputtering gas, thereby cleaning the surface. Subsequently, the metallic layer 23 was formed with a thickness of 4 μm by sputtering with a metal iron target at a degree of vacuum of 0.6 Pa and a sputter input power of 2 kW for 20 minutes. After that, the masking was peeled off. The surface of the portion except for the metallic layer 23 was then coated with the resin paint coating film 24 used in the step shown in FIG. 4(2) of Example 1.

In connection with the sputter formation time for fabricating the metallic layer 23 which was an iron film having a thickness of 4 μm, films were formed on glass substrates attached to the substrate holder by using the same device and changing the film formation time, a calibration line representing the relationship between the thickness of the films and the film formation time was plotted, and the sputter formation time was determined using the calibration line.

The porous layer 21 was produced in the same manner as in Example 1. A suspension obtained by mixing an aqueous solution prepared by dissolving 487 g (=1.75 mol) of ferrous sulfate (FeSO₄.7H₂O) and 5 g of ascorbic acid in 800 ml of water prepared by distillation in nitrogen gas and an alkaline aqueous solution prepared by dissolving 216 g of sodium hydroxide (NaOH) in 400 ml of water was used as the treatment liquid. The molar ratio of alkali to the total amount of metal ions in the treatment liquid in this example was 3.1. A hydrothermal synthesis reaction was conducted for 48 hours at 120° C. to form a black porous film having a thickness of 80 μm. The treatment liquid composition and hydrothermal synthesis conditions are shown in Table 2.

(2) Material Analysis of Porous Layer

The material analysis of the obtained porous layer 21 was carried out in the same manner as in “(2) Material analysis of porous layer” of Example 1. The results have confirmed that the porous layer of the present example is a porous film similar to that of Example 1 and was made only of a crystal phase of iron ferrite having a high crystallinity and a spinel type crystal structure with a lattice constant a₀=8.40 Å. The SEM image of the surface of the porous layer 21 of this example is shown in FIG. 16.

(3) Evaluation of Durability

A durability test was carried out in the same manner as in “(5) Evaluation of durability” of Example 1. The results are shown in Table 4. It was apparent from these results that, as in Example 1, peeling of the porous layer is not observed even after 50 hours of the durability test.

### Example 13

(1) Engine Valve Having a Porous Layer and Fabrication Thereof

In the present embodiment, the internal combustion engine component having a porous layer is an engine valve 5 having the same size as that shown in Example 1. However, it differs from Example 1 in the following aspects. The first difference is that the composition of the base material 22 is a carbon steel. The second difference is that the metallic layer 22 is not present and the porous layer 23 having a thickness of 80 μm is formed such that the porous layer 21 is in direct contact with the surface of the base material 22.

A black porous layer 22 was formed in the same manner as in Example 1 by carrying out a hydrothermal synthesis reaction for 48 hours at 120° C. by using the same treatment liquid as in Example 1. The treatment liquid composition and hydrothermal synthesis conditions are shown in Table 2.

(2) Material Analysis of Porous Layer

The material analysis of the obtained porous layer 21 was carried out in the same manner as in “(2) Material analysis of porous layer” of Example 1. It was confirmed from the results that the porous layer of the present example is a porous film similar to that of Example 1 that is made only of iron ferrite having a high crystallinity and a spinel type crystal structure with a lattice constant a₀=8.40 Å. The SEM image of the surface of the porous layer 21 of this example is shown in FIG. 16.

(3) Evaluation of Durability

A durability test was carried out in the same manner as in “(5) Evaluation of durability” of Example 1. The results are shown in Table 4. It was apparent from these results that, as in Example 1, peeling of the porous layer is not observed even after 50 hours of the durability test.

### Example 14

(1) Engine Piston Having a Porous Layer and Fabrication Thereof

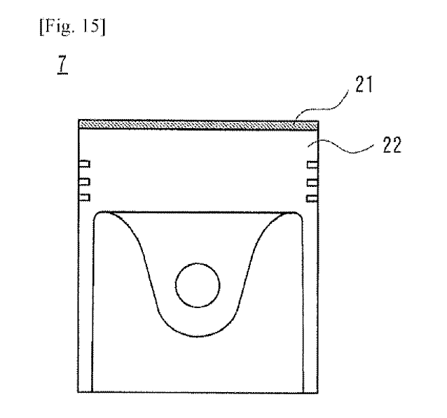

In the present example, the internal combustion engine component having a porous layer of the present invention is a piston 7 having the configuration shown in FIG. 15. The size of the piston is 79 mm in diameter×35 mm in height, and the material of the base material 22 constituting this piston 7 is cast iron.

As shown in FIG. 15, a porous layer 21 having a thickness of 80 μm was directly disposed on the top surface of the piston 7 of this example. The abovementioned porous layer 21 was a porous film of ferrite similar to that of Example 1.

The porous layer was formed in the following manner. Initially, the base material of the piston was prepared, only the top face of the piston was left and the surface of other portions was covered with a resin paint coating film. Subsequently, a hydrothermal synthesis reaction was carried out for 48 hours at 120° C. by using the same treatment liquid as described in Example 1, thereby forming the porous layer 22 formed of a black film on the top surface portion in the same manner as in Example 1. The treatment liquid composition and hydrothermal synthesis conditions are shown in Table 2. Finally, the resin paint coating film was peeled off, and the piston 7 having a porous layer having a thickness of 80 μm on the top surface was fabricated.

(2) Material Analysis of Porous Layer

The material analysis of the obtained porous layer 21 was carried out in the same manner as in “(2) Material analysis of porous layer” of Example 1. The results have shown that the porous layer of the present example is a porous film similar to that of Example 13 that is made only of iron ferrite having a spinel type crystal structure with a high crystallinity and a lattice constant a₀=8.40 Å. That is, the porous layer was a porous film of a crystalline iron ferrite formed by crystal grains of the ferrite which were three-dimensionally interconnected in a dendritic manner. Thus, the SEM image of the surface of the porous layer 21 of this example is shown in FIG. 16.

### INDUSTRIAL APPLICABILITY

The component of the present invention can be advantageously used as a component constituting the combustion chamber of an internal combustion engine for an automobile, a motorcycle, a ship or the like, for example, an engine valve, a cylinder head, a cylinder liner, a piston, and the like.

1. An internal combustion engine component constituting an inner wall surface of a combustion chamber of an internal combustion engine, wherein
(1) in the component, a porous layer is formed at least on a surface exposed to an atmosphere within the combustion chamber, and
(2) the porous layer is a layer formed by three-dimensionally interconnected grains of a ferrite which is an iron oxide.

2. The internal combustion engine component according to claim 1, wherein
the porous layer is formed of dendritic clusters of the ferrite that continuously extend upward from
1) a surface of a base material of the component or
2) a surface of a metallic film which has been formed in advance on the surface of the base material of the component.

3. The internal combustion engine component according to claim 1, wherein the porous layer is formed by a hydrothermal synthesis reaction of 1) a surface of a base material of the component or 2) a surface of a metallic film which has been formed in advance on the surface of the base material of the component, and an aqueous solution or an aqueous dispersion containing an iron component.

4. The internal combustion engine component according to claim 1, wherein the ferrite which is a spinel type oxide is an oxide having a spinel type crystal structure represented by a following general formula: AₓFe₃₋ₓO₄ where A represents at least one kind of metal element substitutable for a Fe site constituting a crystal of a spinel type iron oxide, and x satisfies 0□x<1.

5. The internal combustion engine component according to claim 4, wherein A is at least one of Al, Mg, Mn and Zn.

6. The internal combustion engine component according to claim 1, wherein a base material is made of iron or an alloy including the same.

7. The internal combustion engine component according to claim 1, wherein a surface of a base material is nitrided in advance.

8. The internal combustion engine component according to claim 2, wherein the metallic layer includes an iron-containing layer.

9. The internal combustion engine component according to claim 8, wherein the metallic layer has two or more layers of different materials, and a layer in contact with the porous layer is the iron-containing layer.

10. The internal combustion engine component according to claim 1, wherein the porous layer has a thickness of 40 μm or more.

11. The internal combustion engine component according to claim 1, wherein the component is a valve.

12. The internal combustion engine component according to claim 1, wherein the component is a piston.

13. A method for producing an internal combustion engine component having, on the surface thereof, a porous layer formed by three-dimensionally interconnected grains of a ferrite which is an iron oxide,
the method comprising a step of causing a hydrothermal synthesis reaction of 1) a surface of a base material of the component or 2) a surface of a metallic layer which has been formed in advance on the surface of the base material of the component, and an aqueous solution or an aqueous dispersion containing an iron component, to form the porous layer on the surface.

14. The production method according to claim 13, wherein the hydrothermal synthesis reaction comprises a step of performing heat treatment under an environment at or above a saturated water vapor pressure at 105° C. to 150° C. in a state in which 1) the surface of the base material of the component or 2) the surface of the metallic layer which has been formed in advance on the surface of the base material of the component, is in contact with a treatment liquid obtained by mixing a metal salt, an alkali and water.

15. The production method according to claim 13, wherein the metallic layer is formed by a plating method or a sputtering method.

16. The production method according to claim 13, wherein the hydrothermal synthesis reaction is carried out in the presence of a reducing agent.
